(19) United States
(12) Patent Application Publication
(10) Pub. No.: US 2025/0386716 A1
(43) Pub. Date: Dec. 18, 2025

(54) DISPLAY DEVICE, HEAD MOUNTED DISPLAY DEVICE, AND ELECTRONIC DEVICE

(71) Applicant: Samsung Display Co., Ltd., Yongin-si (KR)

(72) Inventors: Ji Won LEE, Yongin-si (KR); Yong Kyu KANG, Yongin-si (KR)

(21) Appl. No.: 19/094,527

(22) Filed: Mar. 28, 2025

(30) Foreign Application Priority Data
Jun. 17, 2024 (KR) 10-2024-0078257
Aug. 19, 2024 (KR) 10-2024-0110251

(51) Int. Cl. H10K 59/80; H10K 59/122

(52) U.S. Cl. CPC H10K 59/879; H10K 59/122

(57) ABSTRACT

A display device includes a first surface emitting light in a first direction and a second surface, an optical unit on the first surface, a display panel including a first, second and third sub-pixels, a pixel defining layer including a first, second, and third openings, defining an emission area of the first to third sub-pixels, respectively, and first, second, and third lenses on the pixel defining layer, the optical unit includes a lens unit transmitting the light, a first infrared light source, and a camera, the display device includes a lens movement unit moving the lens unit, at least one of a center of the first lens and a center of the first opening, a center of the second lens and a center of the second opening, and a center of the third lens and a center of the third opening may not coincide with each other.

### CROSS-REFERENCE TO RELATED APPLICATION

The present application claims priority to and the benefit of Korean Patent Application No. 10-2024-0078257, filed on Jun. 17, 2024, and Korean Patent Application No. 10-2024-0110251, filed on Aug. 19, 2024, in the Korean Intellectual Property Office, the entire disclosures of each of which are incorporated herein by reference.

### BACKGROUND

### 1. Field

Aspects of some embodiments of the present disclosure relate to a display device, a head mounted display device and an electronic device.

### 2. Description of the Related Art

As information technology develops, the importance of display devices as a connection medium between users and information is increasing. In response to this, use of display devices such as liquid crystal display devices and organic light emitting display devices is increasing.

Recently, a head mounted display device (HMD) is being developed as a type of the display device. The HMD is a display device that may be worn on a user's head and displays images, and is currently in a commercialization stage and is being widely applied in various fields such as an entertainment industry.

For example, the HMD may be used in various applications such as virtual reality (VR) and augmented reality (AR). Meanwhile, a method for relatively improving display quality of the HMD is continuously being sought.

The above information disclosed in this Background section is only for enhancement of understanding of the background and therefore the information discussed in this Background section does not necessarily constitute prior art.

### SUMMARY

Aspects of some embodiments of the present disclosure include a display device, a head mounted display device, and an electronic device capable of relatively improving display quality.

According to some embodiments of the present disclosure, a display device may include a display unit including a first surface emitting light in a first direction and a second surface opposite to the first surface, an optical unit on the first surface of the display unit, the display unit may include a display panel which includes a first sub-pixel, a second sub-pixel, and a third sub-pixel, a pixel defining layer including a first opening, a second opening, and a third opening defining an emission area of the first to third sub-pixels, respectively, and a first lens, a second lens, and a third lens on the pixel defining layer, the optical unit may include a lens unit transmitting the light, a first infrared light source, and a camera, the display device may further include a lens movement unit moving the lens unit, at least one of a center of the first lens and a center of the first opening, a center of the second lens and a center of the second opening, or a center of the third lens and a center of the third opening may not coincide with each other.

According to some embodiments, the lens unit may include a pancake lens, and the pancake lens may include a first polarizing layer, a first quarter wave plate, a partial reflection mirror layer, a second quarter wave plate, and a second polarizing layer.

According to some embodiments, the first sub-pixel may be at a center of the display panel, the center of the first lens and the center of the first opening may overlap in a plan view, the center of the second lens may be shifted by a first distance from the center of the second opening, and the center of the third lens may be shifted by a second distance different from the first distance from the center of the third opening.

According to some embodiments, the display device may include an overcoat layer on the first lens, and each of the first lens, the second lens, and the third lens may have a refractive index higher than that of the overcoat layer.

According to some embodiments, the display device may be worn by a user, and in a state in which the display device is worn by the user, the camera may detect a position of a user's pupil through light emitted from the first infrared light source reflected on the user's pupil.

According to some embodiments, the lens movement unit may move the lens unit in at least one of a direction in which a plane on which the lens unit is located extends or a direction perpendicular to the plane, based on the position of the user's pupil.

According to some embodiments, the display device may further include a panel movement unit moving the display panel, and the panel movement unit may move the display panel in at least one of a direction in which a plane on which the display panel is located extends or a direction perpendicular to the plane, based on the position of the user's pupil.

According to some embodiments, the display device may further include a case unit in which the display unit and the optical unit are received, and a case movement unit rotating the case unit.

According to some embodiments, the display device may be an OLED on silicon (OLEDoS) display device.

According to some embodiments of the disclosure, a head mounted display device may include a display unit including a first surface emitting light in a first direction and a second surface opposite to the first surface, and an optical unit on the first surface of the display unit, the display unit may include a display panel which includes a first sub-pixel, a second sub-pixel, and a third sub-pixel, a pixel defining layer including a first opening, a second opening, and a third opening defining an emission area of the first to third sub-pixels, respectively, and a first lens, a second lens, and a third lens on the pixel defining layer, the lens unit may include a lens unit transmitting the light, a first infrared light source, and a camera, the head mounted display device may further include a lens movement unit moving the lens unit, and a panel movement unit moving the display panel, in a state in which the head mounted display device is worn by a user, the camera may detect a position of a user's pupil through light emitted from the first infrared light source reflected on the user's pupil, at least one of a center of the first lens and a center of the first opening, a center of a second lens and a center of the second opening, or a center of the third lens and a center of the third opening may not coincide with each other, and the lens movement unit and the panel movement unit may move the lens unit and the display panel, respectively, according to the position of the user's pupil.

According to some embodiments, the lens unit may include a pancake lens, and the pancake lens may include a polarizing layer, a quarter wave plate, and a partial reflection mirror layer, and at least one surface of the polarizing layer, the quarter wave plate, and the partial reflection mirror layer may be a curved surface.

According to some embodiments, the first sub-pixel may be at a center of the display panel, the center of the first lens and the center of the first opening may overlap in a plan view, the center of the second lens may be shifted from the center of the second opening by a first distance, and the center of the third lens may be shifted from the center of the third opening by a second distance different from the first distance.

According to some embodiments, the head mounted display device may include an overcoat layer on the first lens, and each of the first lens, the second lens, and the third lens may have a refractive index higher than that of the overcoat layer.

According to some embodiments, the head mounted display device may further include a case unit in which the display unit and the optical unit are received, a fix unit mounting the case unit on a user's head, and a case movement unit between the fix unit and the case unit, and the case movement unit may rotate the case unit to adjust an angle formed by the lens unit and the display panel with a central axis of the user's pupil.

According to some embodiments, when the user's pupil is at a first position, the panel movement unit may move the display panel to cause a center of the user's pupil and a center of the display panel to coincide with each other, and the lens movement unit may move the lens unit to cause the center of the user's pupil and a center of the lens unit to coincide with each other.

According to some embodiments, the display unit may include a first display unit including a first display panel and a second display unit including a second display panel, the optical unit may include a first optical unit including a first lens unit and a second optical unit including a second lens unit, the panel movement unit may include a first panel movement unit moving the first display panel and a second panel movement unit moving the second display panel, and the lens movement unit may include a first lens movement unit moving the first lens unit and a second lens movement unit moving the second lens unit.

According to some embodiments, the first lens movement unit and the second lens movement unit may move the first lens unit and the second lens unit, respectively, so that at least one of a distance between the first lens unit and the second lens unit, or a distance between each of the first lens unit and the second lens unit and a user's eye is adjusted, based on the position of the user's pupil, and the first panel movement unit and the second panel movement unit may move the first display panel and the second display panel, respectively, so that at least one of a distance between the first display panel and the second display panel, or a distance between each of the first display panel and the second display panel and the user's eye is adjusted, based on the position of the user's pupil.

According to some embodiments, the display panel may include a silicon substrate.

According to some embodiments of the present disclosure, an electronic device may include a processor and a display device. The display device may include a display unit including a first surface emitting light in a first direction and a second surface opposite to the first surface, an optical unit on the first surface of the display unit, the display unit may include a display panel which includes a first sub-pixel, a second sub-pixel, and a third sub-pixel, a pixel defining layer including a first opening, a second opening, and a third opening defining an emission area of the first to third sub-pixels, respectively, and a first lens, a second lens, and a third lens on the pixel defining layer, the optical unit may include a lens unit transmitting the light, a first infrared light source, and a camera, the display device may further include a lens movement unit moving the lens unit, at least one of a center of the first lens and a center of the first opening, a center of the second lens and a center of the second opening, or a center of the third lens and a center of the third opening may not coincide with each other.

According to some embodiments of the present disclosure, a display device, a head mounted display device, and an electronic device capable of relatively improving display quality may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram of a display device according to some embodiments;

FIG. 2 is a perspective view schematically illustrating a display device according to some embodiments;

FIG. 3 schematically illustrates an example of an exploded view of the display device of FIG. 2;

FIG. 4 is a schematic plan view of the display device of FIG. 2;

FIG. 5 is a schematic drawing illustrating a movement direction of a display unit and an optical unit;

FIG. 6 is a schematic drawing illustrating a movement direction of a case unit;

FIG. 7 is a schematic plan view illustrating aspects of a display panel;

FIG. 8 is a schematic exploded perspective view illustrating a portion of the display panel of FIG. 7;

FIG. 9 is a schematic cross-sectional view illustrating an arrangement of lenses of FIG. 8;

FIG. 10 is a schematic plan view illustrating aspects of one of the pixels of FIG. 8;

FIG. 11 is a schematic plan view illustrating further details of one of the pixels of FIG. 8;

FIG. 12 is a schematic plan view illustrating further details of one of the pixels of FIG. 8;

FIG. 13 is a schematic cross-sectional view taken along line I-I′ of FIG. 10 according to some embodiments;

FIG. 14 is a schematic cross-sectional view taken along line I-I′ of FIG. 10 according to some embodiments;

FIG. 15 is a schematic enlarged view illustrating area A of FIG. 14;

FIG. 16 is a schematic cross-sectional view illustrating aspects of a portion of a light emitting structure included in one of first to third light emitting elements of FIG. 13 or 14;

FIG. 17 is a schematic cross-sectional view illustrating further details of a portion of the light emitting structure included in one of the first to third light emitting elements of FIG. 13 or FIG. 14; and

FIGS. 18 to 20 are schematic drawings illustrating movement of a display unit and an optical unit according to a user's pupil position.

FIG. 21 is a block diagram of an electronic device according to an embodiment.

FIG. 22 shows schematic views of various embodiments of an electronic device.

### DETAILED DESCRIPTION

The disclosure may be modified in various manners and have various forms. Therefore, specific embodiments will be illustrated in the drawings and will be described in detail in the specification. However, it should be understood that the embodiments according to the present disclosure are not intended to be limited to the specific disclosure forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the disclosure, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and another portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

The disclosure relates to a display device and a head mounted display device. Hereinafter, a display device and a head mounted display device according to some embodiments are described with reference to the attached drawings.

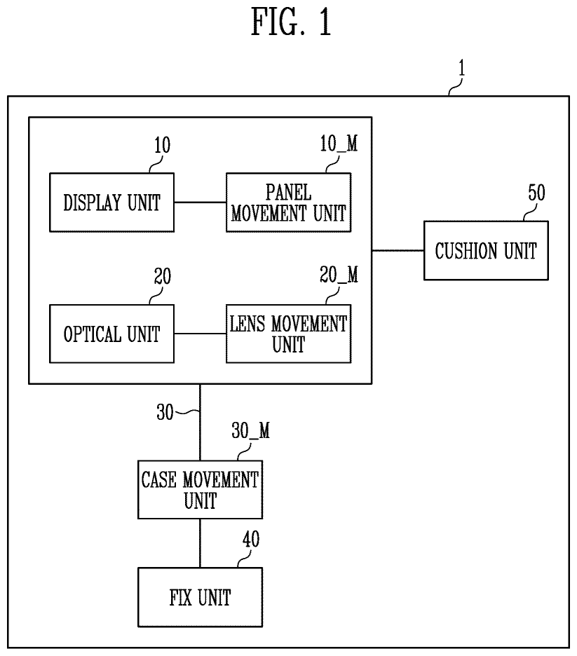

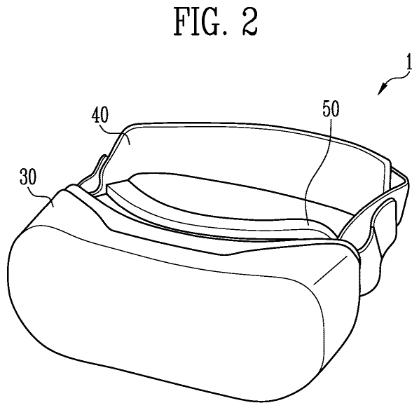

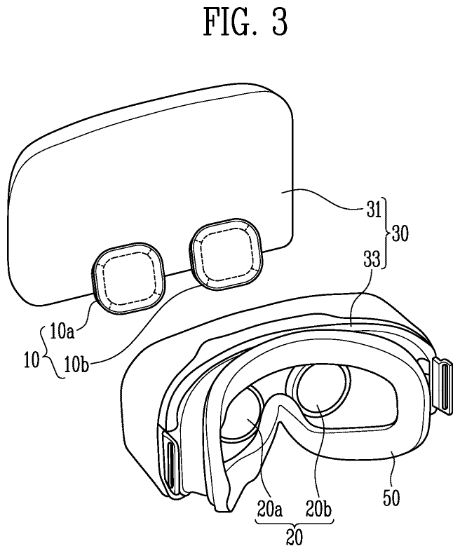

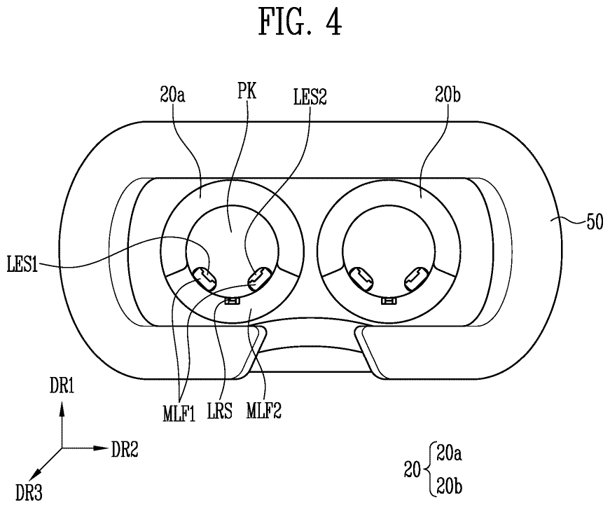

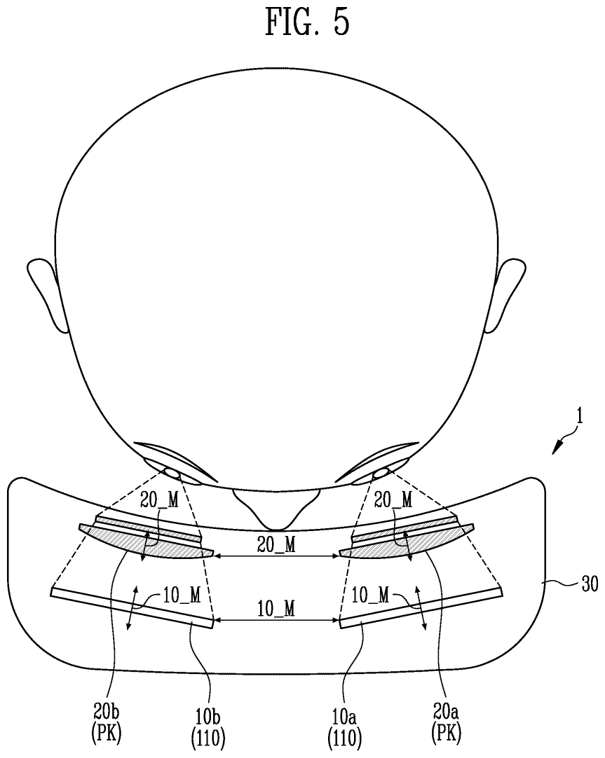

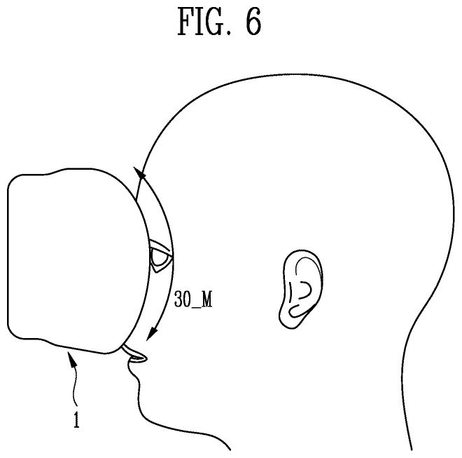

FIG. 1 is a schematic block diagram of a display device according to some embodiments. FIG. 2 is a perspective view schematically illustrating a display device according to some embodiments. FIG. 3 schematically illustrates an example of an exploded view of the display device of FIG. 2. FIG. 4 is a schematic plan view of the display device of FIG. 2. FIG. 5 is a schematic drawing illustrating a movement direction of a display unit and an optical unit. FIG. 6 is a schematic drawing illustrating a movement direction of a case unit.

Referring to FIGS. 1 to 3, the display device 1 may include a head mounted display device configured to be mounted on a head of a user to provide a screen on which a picture or an image is displayed to the user.

The display device 1 may include a see-through type that provides augmented reality based on actual external objects, and a see-closed type that provides virtual reality to the user with a screen independent of an external object. Hereinafter, a see-closed type of head mounted display device is illustrated, embodiments of the present disclosure are not limited thereto.

Referring to FIGS. 1 to 3, the display device 1 may include a display unit 10, an optical unit 20, a case unit 30, a fix unit 40, a cushion unit 50, a panel movement unit 10_M, a lens movement unit 20_M, and a case movement unit 30_M.

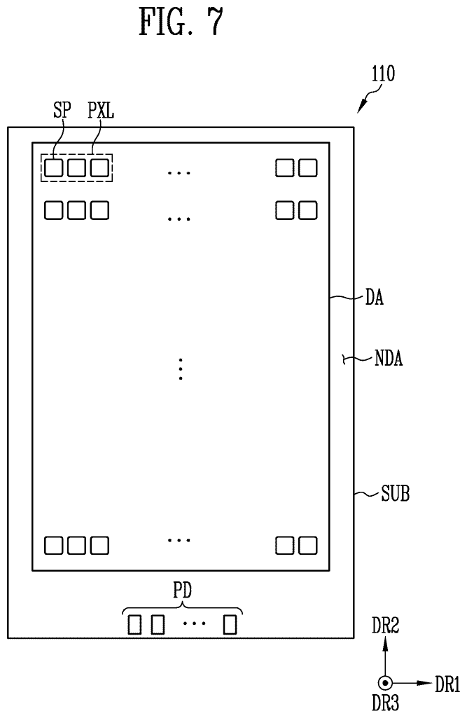

According to some embodiments, the display unit 10 may include a display panel 110 (refer to FIG. 7) and may display images. The display unit 10 may emit light to provide the picture and/or the image. The display unit 10 may be received in the case unit 30. The display unit 10 may be configured to be opaque, transparent, or translucent according to a type of the display device 1. The display unit 10 may include the display panel 110 for displaying the picture or the image. According to some embodiments, the display unit 10 may include a light emitting display panel including a light emitting element. For example, the display unit 10 may include an organic light emitting display panel using an organic light emitting diode including an organic light emitting layer, a micro light emitting diode display panel using a micro light emitting diode (LED), a quantum dot light emitting display panel using a quantum dot LED including a quantum dot light emitting layer, or an inorganic light emitting display panel using an inorganic light emitting element including an inorganic semiconductor.

According to some embodiments, the display unit 10 may include a first display unit 10a and a second display unit 10b. The first display unit 10a may be arranged to face a left eye of the user, and the second display unit 10b may be arranged to face a right eye of the user.

The first display unit 10a and the second display unit 10b may include the same configuration. For example, the first display unit 10a and the second display unit 10b may include a first display panel and a second display panel corresponding to the display panel 110, respectively. Hereinafter, when referring to the first display unit 10a and the second display unit 10b, the first display unit 10a and the second display unit 10b are referred to as the display unit 10.

According to some embodiments, the display unit 10 may include a first surface (or a front surface) emitting light and a second surface (or a rear surface) opposite to the first surface.

According to some embodiments, the optical unit 20 may allow light emitted from the display unit 10 to pass therethrough. The optical unit 20 may refract and/or reflect the light emitted from the display unit 10. According to some embodiments, the optical unit 20 may magnify the image provided by the display unit 10. The optical unit 20 may be located on the first surface of the display unit 10 to face the display unit 10. When the user wears the display device 1, the optical unit 20 may be located between the user and the display unit 10. Therefore, the user may recognize light emitted from the display unit 10 and refracted and/or reflected by the optical unit 20.

According to some embodiments, the optical unit 20 may include a first optical unit 20a and a second optical unit 20b. The first optical unit 20a may be arranged to face the left eye of the user, and may overlap the first display unit 10a. For example, the first optical unit 20a may be located on a first surface of the first display unit 10a. The second optical unit 20b may be arranged to face the right eye of the user, and may overlap the second display unit 10b. For example, the second optical unit 20b may be located on a first surface of the second display unit 10b.

The first optical unit 20a and the second optical unit 20b may include the same configuration, and hereinafter, when referring to the first optical unit 20a and the second optical unit 20b, the first optical unit 20a and the second optical unit 20b are referred to as the optical unit 20.

Referring to FIG. 4, according to some embodiments, the optical unit 20 may include a pancake lens PK (or a lens unit), a first lens frame MLF1, a second lens frame MLF2, a first infrared light source LES1, a second infrared light source LES2, and a camera LRS.

As described above, each of the first optical unit 20a and the second optical unit 20b may include the pancake lens PK (or the lens unit), the first lens frame MLF1, the second lens frame MLF2, the first infrared light source LES1, the second infrared light source LES2, and the camera LRS. Hereinafter, the pancake lens PK included in the first optical unit 20a is defined as a first lens unit, and the pancake lens PK included in the second optical unit 20b is defined as a second lens unit.

The pancake lens PK (or the lens unit) may transmit allow light emitted from the display unit 10 to pass therethrough. According to some embodiments, the pancake lens PK may include a first polarizing layer, a first quarter wave plate, a partial reflection mirror layer, a second quarter wave plate, and a second polarizing layer. According to some embodiments, the pancake lens PK may have a structure in which the first polarizing layer, the first quarter wave plate, the partial reflection mirror layer, the second quarter wave plate, and the second polarizing layer are sequentially arranged in a direction away from the first surface of the display unit 10. However, embodiments of the present disclosure are not limited thereto.

The pancake lens PK may further include another configuration in addition to the first polarizing layer, the first quarter wave plate, the partial reflection mirror layer, the second quarter wave plate, and the second polarizing layer. For example, the pancake lens PK may further include at least one of various types of lenses, such as a convex lens, a concave lens, a spherical lens, an aspherical lens, a single lens, a compound lens, a standard lens, a narrow-angle lens, a wide-angle lens, a fixed-focus lens, or a variable-focus lens. Alternatively, according to some embodiments, one configuration among the first polarizing layer, the first quarter wave plate, the partial reflection mirror layer, the second quarter wave plate, and the second polarizing layer may be omitted from the pancake lens PK. For example, the pancake lens PK may include the polarizing layer, the quarter wave plate, and the partial reflection mirror layer.

A surface of at least one of configurations included in the pancake lens may be a curved surface. For example, a surface of at least one of the first polarizing layer, the first quarter wave plate, the partial reflection mirror layer, the second quarter wave plate, or the second polarizing layer may be a curved surface.

The first polarizing layer may have a transmission axis (or a pass axis) aligned along one direction. Hereinafter, according to some embodiments, the first polarizing layer may be a linear polarizing layer. The first polarizing layer may linearly polarize light passing through the first polarizing layer. For example, only light vibrating along the transmission axis of the first polarizing layer may be transmitted, and remaining light may not be transmitted.

The first quarter wave plate may have an optical axis aligned at an angle (for example,) 45° with respect to the transmission axis of the first polarizing layer. The first quarter wave plate may change linear polarization to circular polarization or may change circular polarization to linear polarization by providing a phase difference of N4. For example, in a case where light passing through the first polarizing layer has linear polarization of 0°, the light may be left-circularly polarized (LCP) when passing through the first quarter wave plate. However, embodiments of the present disclosure are not limited thereto. According to some embodiments, light passing through the first polarizing layer may be right-circularly polarized (RCP) when passing through the first quarter wave plate.

The partial reflection mirror layer may include a metal mirror coating or other mirror coatings such as a dielectric multilayer coating that transmits 50% and reflects 50% on a surface.

The second quarter wave plate may provide a phase difference of N4.

The second polarizing layer may have a transmission axis (or pass axis) aligned perpendicular to the transmission axis of the first polarizing layer. The second polarizing layer may be a reflective polarizing layer. For example, the second polarizing layer may transmit only light that vibrates along the transmission axis of the second polarizing layer, and reflect remaining light.

The display device 1 according to the disclosure may include the optical unit 20 that includes the pancake lens PK to fold a path of light, thereby reducing a thickness of the display device 1.

According to some embodiments, the first infrared light source LES1, the second infrared light source LES2, and the camera LRS may be sensors for detecting a gaze direction in which a user wearing the display device 1 gazes and a position of a user's pupil. The display device 1 may track a user's gaze and detect the position of the pupil through the first infrared light source LES1 and the camera LRS, but may further include the second infrared light source LES2 to secure reliability.

According to some embodiments, the first infrared light source LES1 and the second infrared light source LES2 may emit infrared light. The camera LRS may convert light incident through the camera LRS into an electrical signal. For example, the camera LRS may include a semiconductor device such as a charged coupled device (CCD) or a complementary metal-oxide semiconductor (CMOS).

The camera LRS may detect the user's pupil and track the user's gaze direction by converting light emitted from the first infrared light source LES1 and/or the second infrared light source LES2 reflected on the user's pupil into an electrical signal. The tracked gaze direction may be utilized to move a center of a virtual image correspondingly to the gaze direction.

According to some embodiments, the first lens frame MLF1 may be a structure for supporting at least a portion of the pancake lens PK. The first lens frame MLF1 may include recess structures in which the first infrared light source LES1, the second infrared light source LES2, and the camera LRS are mounted.

According to some embodiments, the second lens frame MLF2 may be a structure for supporting and/or protecting at least a portion of the pancake lens PK and the first lens frame MLF1.

According to some embodiments, the first infrared light source LES1 and the second infrared light source LES2 may be mounted on the first lens frame MLF1 and may be provided spaced apart from the pancake lens PK at a distance (e.g., a set or predetermined distance).

According to some embodiments, the camera LRS may be positioned in an area adjacent to the first infrared light source LES1 and the second infrared light source LES2, and may be positioned between the first infrared light source LES1 and the second infrared light source LES2. According to some embodiments, the camera LRS may be positioned in a direction intersecting a direction facing the user's pupil in a state in which the display device is worn by a user (e.g., a worn state). For example, when it is assumed that a first direction DR1 and a second direction DR2 are directions in which a plane where the pancake lens PK (or the display panel 110) is arranged is extended, a third direction DR3 intersecting the first direction DR1 and the second direction DR2 may be a direction facing the user's pupil, and the camera LRS may be arranged in the second direction DR2. The first infrared light source LES1 may be located on a left side with respect to the camera LRS. The second infrared light source LES2 may be located on a right side with respect to the camera LRS.

According to some embodiments, the first infrared light source LES1, the second infrared light source LES2, and the camera LRS may be located at a position adjacent to a lower portion of the user's pupil when the user wears the display device 1.

According to some embodiments, as the first infrared light source LES1, the second infrared light source LES2, and the camera LRS is located in an area adjacent to a lower portion of the user's pupil, interference by an object (for example, user's eyelashes) may be prevented, reduced (or minimized). Therefore, the first infrared light source LES1, the second infrared light source LES2, and the camera LRS may detect information on the user's pupil position and the gaze direction with relatively improved reliability.

In addition, as the first infrared light source LES1 and the second infrared light source LES2 are mounted and located on a structure of the first lens frame MLF1, the first infrared light source LES1 and the second infrared light source LES2 may be located adjacent to the pancake lens PK and may spaced apart from the pancake lens PK. Therefore, light may be emitted toward the user's pupil while minimizing interference due to a shape of the pancake lens PK.

According to some embodiments, the case unit 30 may receive the display unit 10 and the optical unit 20. The case unit 30 may have a space therein, and the display unit 10 and the optical unit 20 may be located in the space. The case unit 30 may protect the display unit 10 and the optical unit 20 from external impact.

According to some embodiments, the case unit 30 may include a cover unit 31 and a body unit 33. The case unit 30 may be separated into each of the cover unit 31 and the body unit 33, but is not limited thereto, and the cover unit 31 and the body unit 33 may be integrally formed. According to some embodiments, the cover unit 31 may be located on the rear surface of the display unit 10, and the body unit 33 may be located on the front surface of the display unit 10.

The fix unit 40 may mount the case unit 30 on the head of the user. A length of the fix unit 40 may be adjusted according to a circumference of the head of the user. The fix unit 40 may include a structure such as a strap or a band connected to the case unit 30. The fix unit 40 may be attachable to or detachable from the case unit 30.

According to some embodiments, the cushion unit 50 may relatively improve a wearing comfort to the user. When the user wears the display device 1, the cushion unit 50 may be located between the user and the case unit 30. According to some embodiments, the cushion unit 50 may be attached to the case unit 30. According to some embodiments, the cushion unit 50 may be detachable from the case unit 30, and may be omitted from the display device 1.

According to some embodiments, the display device 1 may further include a controller. The controller may include a first controller and a second controller.

The first controller may perform an operation for calculation of the position of the user's pupil, calculation of the gaze direction of the user, image processing (for example, image mapping) based on the calculated position of the user's pupil (or the gaze direction), displaying a processed image on the display unit 10, and the like, and may provide obtained information.

The second controller may generate a signal for driving the panel movement unit 10_M, the lens movement unit 20_M, and the case movement unit 30_M using the information received from the first controller, and the panel movement unit 10_M, the lens movement unit 20_M, and the case movement unit 30_M may be driven according to the signal.

According to some embodiments, information related to an efficient arrangement relationship of the display unit 10 and the optical unit 20 according to the pupil position of the user and the gaze direction of the user may be input to the first controller in advance. According to some embodiments, the second controller may drive the panel movement unit 10_M, the lens movement unit 20_M, and the case movement unit 30_M based on the pupil position of the user and the gaze direction of the user calculated from the first controller. According to some embodiments, the second controller may drive the panel movement unit 10_M, the lens movement unit 20_M, and the case movement unit 30_M according to information related to the efficient arrangement relationship of the display unit 10 and the optical unit 20.

The efficient arrangement relationship of the display unit 10 and the optical unit 20 may be determined according to the pancake lens PK, the display panel 110, and the pupil position of the user. For example, the efficient arrangement relationship of the display unit 10 and the optical unit 20 may be determined through a simulation that measures at least one of a lateral color shift or a relative luminance value according to an arrangement relationship between the pupil position of the user, the pancake lens PK, and the display panel 110. Through the above-described simulation, the efficient arrangement relationship of the display unit 10 and the optical unit 20 according to the pupil position of the user may be determined, and this may be input to the display device 1 in advance.

In the disclosure, embodiments in which the first controller and the second controller are separately configured is illustrated, but embodiments of the present disclosure are not limited thereto. According to some embodiments, one controller may perform a function of the first controller and the second controller.

The controller may be implemented as a dedicated processor including an embedded processor or the like, a general-purpose processor including a central processing unit, an application processor, or the like, and/or the like, but is not limited thereto.

Referring to FIGS. 1 and 5, the panel movement unit 10_M may adjust a distance between the display unit 10 and the eye, a distance between the display unit 10 and the optical unit 20, and a distance between the display units 10 based on the pupil position of the user and the direction of the gaze. The panel movement unit 10_M may move the display unit 10. The panel movement unit 10_M may move the display panel 110 of the display unit 10.

The panel movement unit 10_M may include a first panel movement unit and a second panel movement unit, the first panel movement unit may move the first display panel, and the second panel movement unit may move the second display panel.

The panel movement unit 10_M may move the display panel 110 in a direction perpendicular to the direction in which the plane where the display panel 110 is located extends (for example, in an up-down direction) so that the distance between the display unit 10 and the eye and the distance between the display unit 10 and the optical unit 20 are adjusted. According to some embodiments, the panel movement unit 10_M may adjust an eye relief distance by adjusting the distance between the display unit 10 and the eye according to whether the user wears glasses.

For example, the first panel movement unit may move the first display panel in the up-down direction, the second panel movement unit may move the second display panel in the up-down direction, and thus the distance between the display unit 10 and the eye and the distance between the display unit 10 and the optical unit 20 may be adjusted.

The panel movement unit 10_M may move the display panel 110 in a direction parallel to the direction in which the plane where the display panel 110 is located extends (for example, in a left-right direction) so that the distance between the first display unit 10a and the second display unit 10b may be adjusted.

For example, the first panel movement unit may move the first display panel in the left-right direction, the second panel movement unit may move the second display panel in the left-right direction, and the distance between the first display unit 10a and the second display unit 10b may be adjusted. For example, the distance between the first display unit 10a and the second display unit 10b may be adjusted to correspond to the distance between the user's eye.

According to some embodiments, the panel movement unit 10_M may be located adjacent to the display unit 10. For example, at least a portion of the panel movement unit 10_M may be detachably coupled with at least a portion of the display unit 10. Alternatively, at least a portion of the panel movement unit 10_M and at least a portion of the display unit 10 may be integrally coupled.

The lens movement unit 20_M may adjust a distance between the optical unit 20 and the eye, a distance between the display unit 10 and the optical unit 20, and a distance between the optical units 20 based on the pupil position of the user and the direction of the gaze. The lens movement unit 20_M may move the pancake lens PK of the optical unit 20.

The lens movement unit 20_M may include a first lens movement unit and a second lens movement unit, the first lens movement unit may move the pancake lens PK (the first lens unit) of the first optical unit 20a, and the second lens movement unit may move the pancake lens PK (the second lens unit) of the second optical unit 20b.

The lens movement unit 20_M may move the pancake lens of the optical unit 20 in a direction perpendicular to a plane where the pancake lens is located (for example, in the up-down direction) so that the distance between the optical unit 20 and the eye and the distance between the optical unit 20 and the display unit 10 are adjusted.

For example, the first lens movement unit may move the first lens unit in the up-down direction, the second lens movement unit may move the second lens unit in the up-down direction, and thus the distance between the optical unit 20 and the eye and the distance between the display unit 10 and the optical unit 20 may be adjusted.

The lens movement unit 20_M may move the pancake lens PK in a direction parallel to a direction in which a plane where the pancake lens PK is located extends (for example, in the left-right direction) so that a distance between the first lens unit and the second lens unit is adjusted. For example, the lens movement unit 20_M may move the pancake lens in the left-right direction.

For example, the first lens movement unit may move the first lens unit in the left-right direction, the second lens movement unit may move the second lens unit in the left-right direction, and the distance between the first lens unit and the second lens unit may be adjusted. For example, the distance between the first lens unit and the second lens unit may be adjusted so that the first lens unit and the second lens unit correspond to a distance between the user's eyes.

According to some embodiments, the lens movement unit 20_M may be located adjacent to the optical unit 20. For example, at least a portion of the lens movement unit 20_M may be detachably coupled with at least a portion of the pancake lens PK of the optical unit 20. Alternatively, at least a portion of the lens movement unit 20_M and at least a portion of the pancake lens PK of the optical unit 20 may be integrally coupled.

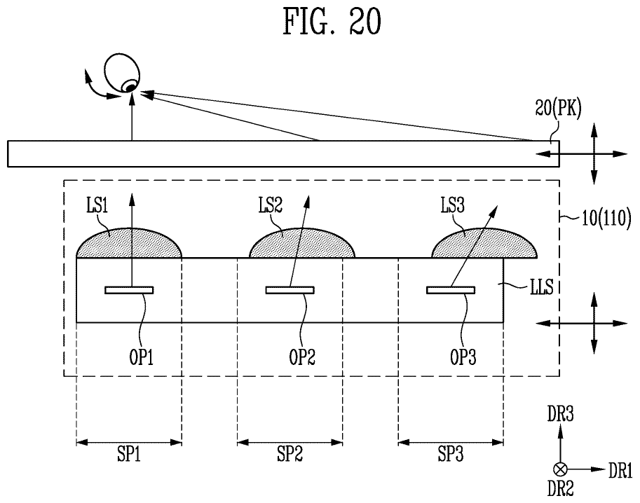

By the panel movement unit 10_M and the lens movement unit 20_M, the display panel 110 and the pancake lens may be aligned to display an image with relatively improved display quality to the user. For example, according to some embodiments, based on the position of the user's pupil and the direction of the user's gaze, the panel movement unit 10_M and the lens movement unit 20_M may adjust positions of the display panel 110 and the pancake lens PK, respectively, so that a center of the display panel 110, a center of the pancake lens PK, and a center of the pupil coincide with each other. This is described later with reference to FIGS. 18 to 20.

Referring to FIGS. 1 and 6, the case movement unit 30_M may adjust a position of the case unit 30 so that an angle formed by the display unit 10 (or the display panel 110) and the optical unit 20 (or the pancake lens PK) with a center axis of the user's pupil is adjusted based on the position of the user's pupil and the direction of the user's gaze. The case movement unit 30_M may move the case unit 30. For example, the case movement unit 30_M may rotate the case unit 30.

According to some embodiments, the case movement unit 30_M may be positioned adjacent to the case unit 30. For example, the case movement unit 30_M may be positioned in an area where the case unit 30 and the fix unit 40 are connected (for example, between the case unit 30 and the fix unit 40) to rotate the case unit 30 relative to the fix unit 40 when the fix unit 40 is fixed to the user's head.

Hereinafter, the display panel 110 included in the display part 10 is described with reference to FIGS. 7 to 17. The display panel 110 according to the disclosure may reduce x-talk for each light color of the display device 1 and relatively improve a luminance of light.

FIG. 7 is a schematic plan view illustrating aspects of a display panel.

Referring to FIG. 7, the display panel 110 may include a display area DA and a non-display area NDA. The display panel 110 displays an image through the display area DA. The non-display area NDA is arranged around the display area DA.

The display panel 110 may include a substrate SUB, the sub-pixels SP, and pads PD.

When the display panel 110 is used as a display screen of a head mounted display (HMD), a virtual reality (VR) device, a mixed reality (MR) device, an augmented reality (AR) device, or the like, the display panel 110 may be positioned very close to user's eyes. In this case, sub-pixels SP of a relatively high integration degree are required. In order to increase an integration degree of the sub-pixels SP, the substrate SUB may be provided as a silicon substrate. The sub-pixels SP and/or the display panel 110 may be formed on the substrate SUB, which is the silicon substrate. The display device 1 (refer to FIG. 1) including the display panel 110 formed on the substrate SUB, which is the silicon substrate, may be referred to as an OLED on silicon (OLEDOS) display device.

The sub-pixels SP are located in the display area DA on the substrate SUB. The sub-pixels SP may be arranged in a matrix shape along the first direction DR1 and the second direction DR2 intersecting the first direction DR1. However, embodiments according to the present disclosure are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction. In addition, the third direction DR3 may be a direction perpendicular to the first direction DR1 and the second direction DR2 (or the direction perpendicular to the direction in which the plane where the display panel 110 is located extends).

Two or more sub-pixels among the plurality of sub-pixels SP may configure one pixel PXL.

A component for controlling the sub-pixels SP may be located in the non-display area NDA on the substrate SUB. For example, lines connected to the sub-pixels SP, such as gate lines and data lines may be located in the non-display area NDA.

The pads PD are located in the non-display area NDA on the substrate SUB. The pads PD may be electrically connected to the sub-pixels SP through lines. For example, the pads PD may be connected to the sub-pixels SP through the data lines.

The pads PD may interface the display panel 110 to other components of the display device 1. According to some embodiments, voltages and signals necessary for an operation of components included in the display panel 110 may be provided through the pads PD.

According to some embodiments, a circuit board may be electrically connected to the pads PD using a conductive adhesive member such as an anisotropic conductive film. At this time, the circuit board may be a flexible circuit board (FPCB) or a flexible film having a flexible material. A driver integrated circuit may be mounted on the circuit board to be electrically connected to the pads PD.

According to some embodiments, the display area DA may have various shapes. The display area DA may have a closed loop shape including straight and/or curved sides. For example, the display area DA may have shapes such as a polygon, a circle, a semicircle, and an ellipse.

According to some embodiments, the display panel 110 may have a flat display surface. According to some embodiments, the display panel 110 may have a display surface that is at least partially round. According to some embodiments, the display panel 110 may be bendable, foldable, or rollable. In these cases, the display panel 110 and/or the substrate SUB may include materials having a flexible property.

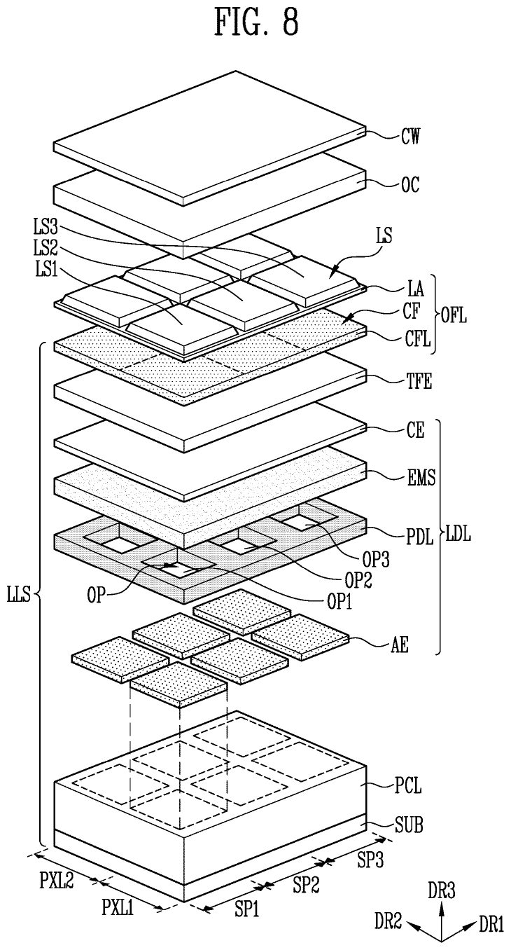

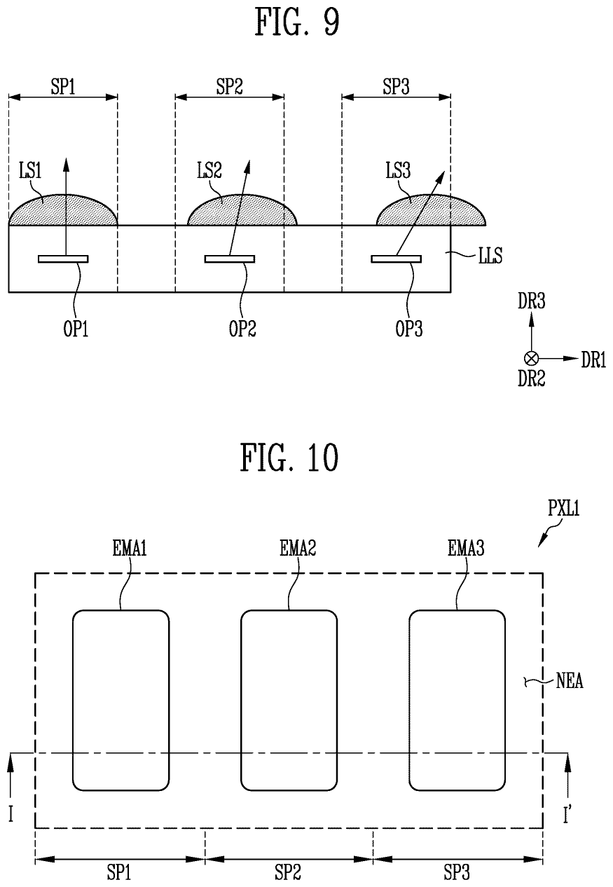

FIG. 8 is a schematic exploded perspective view illustrating a portion of the display panel of FIG. 7. In FIG. 8, for clarity and concise description, a portion of the display panel 110 corresponding to two pixels PXL1 and PXL2 among the pixels PXL of FIG. 7 is schematically shown. A portion of the display panel 110 corresponding to remaining pixels may be similarly configured. FIG. 9 is a schematic cross-sectional view illustrating an arrangement of the lenses of FIG. 8. In FIG. 9, for clarity and concise description, configurations located under first to third lenses LS1, LS2, and LS3 of FIG. 8 are shown as a lower structure LLS.

Referring to FIGS. 7 and 8, each of the first and second pixels PXL1 and PXL2 may include first to third sub-pixels SP1, SP2, and SP3. However, embodiments according to the present disclosure are not limited thereto. For example, each of the first and second pixels PXL1 and PXL2 may include four sub-pixels or two sub-pixels.

In FIG. 8, the first to third sub-pixels SP1, SP2, and SP3 have quadrangle shapes when viewed from a third direction DR3 crossing the first and second directions DR1 and DR2, and have sizes equal to each other. However, embodiments according to the present disclosure are not limited thereto. The first to third sub-pixels SP1, SP2, and SP3 may be modified to have various shapes.

The display panel 110 may include the substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOl) layer, or the like. According to some embodiments, the substrate SUB may include a glass substrate. According to some embodiments, the substrate SUB may include a polyimide (PI) substrate.

The pixel circuit layer PCL is located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include copper, but embodiments according to the present disclosure are not limited thereto.

The circuit elements may include a sub-pixel circuit of each of the first to third sub-pixels SP1, SP2, and SP3. The sub-pixel circuit may include transistors and one or more capacitors. Each transistor may include a semiconductor portion including a source area, a drain area, and a channel area, and a gate electrode overlapping the semiconductor portion. According to some embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. According to some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, a data line, and the like.

The light emitting element layer LDL may include the anode electrodes AE, a pixel defining layer PDL, a light emitting structure EMS, and the cathode electrode CE.

The anode electrodes AE may be located on the pixel circuit layer PCL. The anode electrodes AE may contact the circuit elements of the pixel circuit layer PCL. The anode electrodes AE may include an opaque conductive material capable of reflecting light, but embodiments according to the present disclosure are not limited thereto.

The pixel defining layer PDL is located on the anode electrodes AE. The pixel defining layer PDL may include an opening OP exposing a portion of each of the anode electrodes AE. According to the opening OP of the pixel defining layer PDL, emission areas respectively corresponding to the first to third sub-pixels SP1 to SP3 may be defined. For example, the opening OP may include a first opening OP1, a second opening OP2, and a third opening OP3, and the first opening OP1, the second opening OP2, and the third opening OP3 may define the emission areas respectively corresponding to the first to third sub-pixels SP1 to SP3, respectively. Alternatively, it may be understood that the emission areas respectively corresponding to the first to third sub-pixels SP1 to SP3 are defined according to the anode electrodes AE. In an area adjacent to a boundary between neighboring sub-pixels, the pixel defining layer PDL may include a separator that causes a discontinuous portion (discontinuity) to be formed in the light emitting structure EMS. In this case, it may be understood that the emission areas respectively corresponding to the first to third sub-pixels SP1 to SP3 are defined according to the separators of the pixel defining layer PDL.

According to some embodiments, the pixel defining layer PDL may include an inorganic material. In this case, the pixel defining layer PDL may include a plurality of stacked inorganic layers. For example, the pixel defining layer PDL may include silicon oxide (SiOx) and silicon nitride (SiNx). According to some embodiments, the pixel defining layer PDL may include an organic material. However, a material of the pixel defining layer PDL is not limited thereto.

The light emitting structure EMS may be located on the anode electrodes AE exposed by the opening OP of the pixel defining layer PDL. The light emitting structure EMS may include a light emitting layer configured to generate light, an electron transport layer configured to transport an electron, a hole transport layer configured to transport a hole, and the like.

According to some embodiments, the light emitting structure EMS may fill the opening OP of the pixel defining layer PDL, and may be entirely arranged on the pixel defining layer PDL. In other words, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments according to the present disclosure are not limited thereto. For example, portions of the light emitting structure EMS corresponding to the first to third sub-pixels SP1 to SP3 may be separated from each other, and each of the portions may be located in the opening OP of the pixel defining layer PDL.

The cathode electrode CE may be located on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the cathode electrode CE may include at least one of silver (Ag), magnesium (Mg), or a mixture thereof. However, a material of the cathode electrode CE is not limited thereto.

It may be understood that one of the anode electrodes AE, a portion of the light emitting structure EMS overlapping it, and a portion of the cathode electrode CE overlapping it configure one light emitting element. In other words, each of the light emitting elements of the first to third sub-pixels SP1 to SP3 may one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and when the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE is located on the cathode electrode CE. The encapsulation layer TFE may cover the light emitting element layer LDL and/or the pixel circuit layer PCL. The encapsulation layer TFE may be configured to prevent or reduce instances of contaminants such as oxygen, moisture, and/or the like permeating to the light emitting element layer LDL. According to some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material such as acrylic resin, epoxy resin, phenol resin, polyamide resin, polyimide resin, unsaturated polyester resin, poly phenylenether resin, polyphenylenesulfide resin, or benzocyclobutene (BCB). However, materials of the organic layer and the inorganic layer of the encapsulation layer TFE are not limited thereto.

In order to relatively improve an encapsulation efficiency of the encapsulation layer TFE, the encapsulation layer TFE may further include a thin film including aluminum oxide (AIOx). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments according to the present disclosure are not limited thereto. The encapsulation layer TFE may further include a thin film formed of at least one of various materials suitable for relatively improving the encapsulation efficiency.

The optical functional layer OFL is located on the encapsulation layer TFE. The optical functional layer OFL may include a color filter layer CFL and a lens array LA.

The color filter layer CFL is located between the encapsulation layer TFE and the lens array LA. The color filter layer CFL is configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may transmit red color light, the color filter corresponding to the second sub-pixel SP2 may transmit green color light, and the color filter corresponding to the third sub-pixel SP3 may transmit blue color light. In the present specification, the color filter corresponding to the first sub-pixel SP1 is shown as transmitting red color light, the color filter corresponding to the second sub-pixel SP2 is shown as transmitting green color light, and the color filter corresponding to the third sub-pixel SP3 is shown as transmitting blue color light, but embodiments of the present disclosure are not limited thereto. According to some embodiments, according to the light emitted from the light emitting structure EMS of each sub-pixel, at least a portion of the color filters CF may be omitted.

The lens array LA is located on the color filter layer CFL. According to some embodiments, the lens array LA may be a micro array lens. The lens array LA may include lenses LS corresponding to the first to third sub-pixels SP1 to SP3, respectively. For example, the lenses LS may include the first lens LS1 corresponding to the first sub-pixel SP1, the second lens LS2 corresponding to the second sub-pixel SP2, and the third lens LS3 corresponding to the third sub-pixel SP3. In the present specification, correspondence between the first to third sub-pixels SP1 to SP3 and the lenses LS means that respective areas defined by the first to third sub-pixels SP1 to SP3 overlaps the respective lenses LS. For example, the first lens LS1 may overlap an area where the first sub-pixel SP1 is located. The second lens LS2 may overlap an area where the second sub-pixel SP2 is located. The third lens LS3 may overlap an area where the third sub-pixel SP3 is located.

Each of the lenses LS may relatively improve light emission efficiency by outputting light emitted from the light emitting structure EMS to an intended path. The lens array LA (each of the first lens LS1, the second lens LS2, and the third lens LS3) may have a relatively high refractive index. For example, the lens array LA (each of the first lens LS1, the second lens LS2, and the third lens LS3) may have a refractive index higher than that of the overcoat layer OC. According to some embodiments, the lenses LS may include an organic material. According to some embodiments, the lenses LS may include an acrylic material. However, a material of the lenses LS is not limited thereto.

According to some embodiments, compared to the opening OP of the pixel defining layer PDL, at least a portion of the color filters CF of the color filter layer CFL and at least a portion of the lenses LS of the lens array LA may be shifted (or moved) in a direction parallel to the plane defined by the first and second directions DR1 and DR2. For example, in a central area of the display area DA, a center of the color filter CF and a center of the lens LS may be aligned with or overlap with a center of the opening OP of the corresponding pixel definition layer PDL when viewed in the third direction DR3. For example, in the central area of the display area DA, the opening OP of the pixel defining layer PDL may completely overlap the corresponding color filter of the color filter layer CFL and the corresponding lens of the lens array LA. In an area adjacent to the non-display area NDA in the display area DA (for example, an area except for a central area of the display panel 110), the center of the color filter and the center of the lens may be shifted in a plane direction from the center of the opening OP of the corresponding pixel defining layer PDL when viewed in the third direction DR3. For example, in the area adjacent to the non-display area NDA in the display area DA (for example, the area except for the central area of the display panel 110), the center of the color filter and the center of the lens may not coincide with the center of the opening OP of the corresponding pixel defining layer PDL when viewed in the third direction DR3. For example, in the area adjacent to the non-display area NDA in the display area DA, the opening OP of the pixel defining layer PDL may partially overlap a corresponding color filter of the color filter layer CFL and a corresponding lens of the lens array LA.

Specifically, FIG. 9 shows a case where at least a portion of the first to third lenses LS1, LS2, and LS3 is shifted. The first to third sub-pixels SP1, SP2, and SP3 shown in FIG. 9 may correspond to the first to third sub-pixels SP1, SP2, and SP3 shown in FIG. 8. In FIG. 9, it is assumed that a pixel corresponding to the central area of the display area DA is the first sub-pixel SP1, and it is assumed that an area gradually becomes closer to an outer area of the display panel 110 in the first direction DR1 from an area where the first sub-pixel SP1 is located. However, embodiments of the present disclosure are not limited thereto, and the pixel corresponding to the central area of the display area DA may be the second sub-pixel SP2 or the third sub-pixel SP3.

Referring to FIG. 9, a center of the first opening OP1 of the first sub-pixel SP1, which is the pixel corresponding to (or located in) the central area of the display area DA, and a center of the first lens LS1 may coincide with each other. A center of the second opening OP2 of the second sub-pixel SP2, which is a pixel corresponding to (or located in) an area adjacent to the non-display area NDA in the display area DA, and a center of the second lens LS2 may not coincide with each other. A center of the third opening OP3 of the third sub-pixel SP3, which is a pixel corresponding to (or located) in an area adjacent to the non-display area NDA in the display area DA, and a center of the third lens LS3 may not coincide with each other. According to some embodiments, according to a distance from the non-display area NDA (or a distance separated from the center of the display panel 110), a distance by which the lens LS is shifted may be different. For example, the center of the second lens LS2 may be shifted by a first distance from the center of the second opening OP2, and the center of the third lens LS3 may be shifted by a second distance from the center of the third opening OP3. The first distance and the second distance may be different from each other.

As at least a portion of the lenses LS is shifted and arranged, the light emitted from the light emitting structure EMS may be efficiently output in a direction normal to the display surface in the center of the display area DA. In a periphery of the display area DA, the light emitted from the light emitting structure EMS may be efficiently output in a direction inclined by an angle (e.g., a set or predetermined angle) with respect to the direction normal to the display surface. Accordingly, x-talk may be reduced for each light color, and a luminance of light may be relatively improved.

The distance by which the lenses LS are shifted may be changed according to a characteristic of the pancake lens PK. For example, the distance by which the lenses LS are shifted may be determined according to a characteristic of light that the pancake lens PK efficiently transmits for each area. Experimentally, chief ray angle (CRA) values of light that may efficiently pass through a central area of the pancake lens PK and light that may efficiently pass through an outer area of the pancake lens PK may be different from each other. For example, when a center of the pancake lens PK and the center of the display panel 110 coincide with each other, in the central area of the pancake lens PK, light having a first inflow angle may form an appropriate focus to be seen to the user most clearly (or brightly), and in the outer area of the pancake lens PK, light having a second inflow angle different from the first inflow angle may form an appropriate focus to be seen to the user most clearly (or brightly). For example, the central area of the pancake lens PK may be seen to the user most clearly (or brightly) when light emitted vertically from the display panel 110 is incident, and the outer area of the pancake lens PK may be seen to the user most clearly (or brightly) when light at an angle of 20° to 40° with respect to the display panel 110 is incident.

Accordingly, light incident on the central area of the pancake lens PK is required to be incident with the first inflow angle, and light incident on the outer area of the pancake lens PK is required to be incident with the second inflow angle.

According to the disclosure, the lenses LS may output light in a direction inclined by an angle (e.g., a set or predetermined angle) in a partial area of the display panel 110, and thus light that may most efficiently pass through each area of the pancake lens PK may be incident on the pancake lens PK.

The overcoat layer OC may be located on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer or an organic insulating layer. For example, the overcoat layer OC may include epoxy, but embodiments according to the present disclosure are not limited thereto. The overcoat layer OC may have a refractive index lower than that of the lens array LA.

The cover window CW may be located on the overcoat layer OC. The cover window CW is configured to protect layers thereunder. The cover window CW may have a refractive index higher than that of the overcoat layer OC. The cover window CW may include glass, but embodiments according to the present disclosure are not limited thereto. For example, the cover window CW may be an encapsulation glass configured to protect components located thereunder. According to some embodiments, the cover window CW may be omitted.

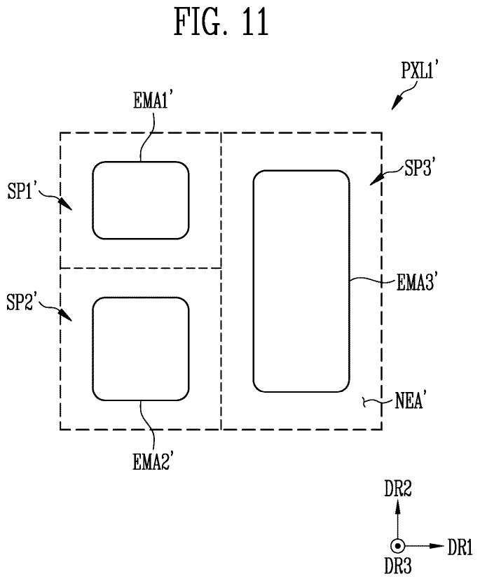

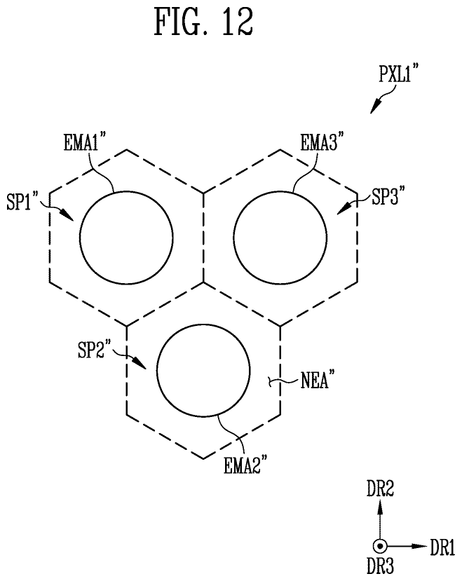

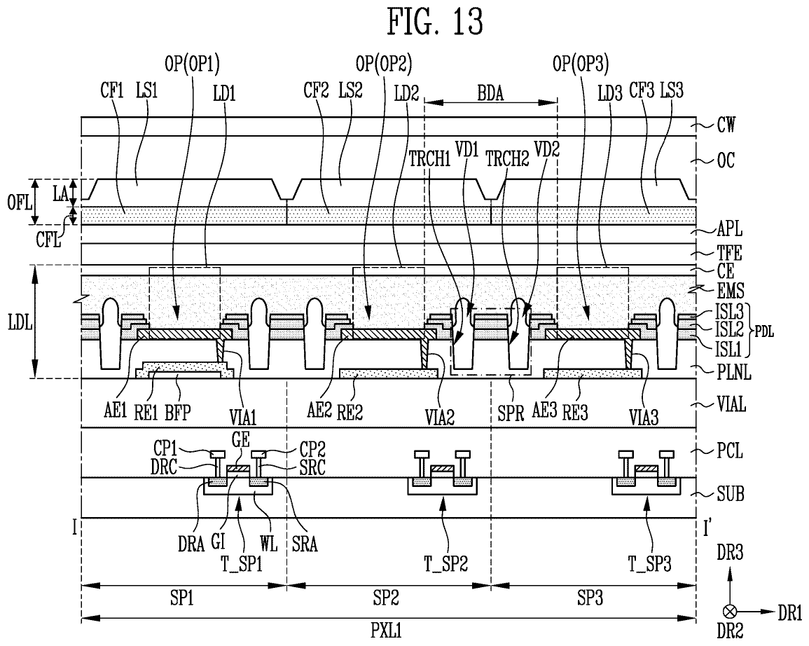

FIG. 10 is a schematic plan view illustrating aspects of one of pixels of FIG. 8. FIG. 11 is a schematic plan view illustrating further details of one of the pixels of FIG. 8. FIG. 12 is a schematic plan view illustrating further details of one of the pixels of FIG. 8.

In FIGS. 10 to 12, the first pixel PXL1 of the first and second pixels PXL1 and PXL2 of FIG. 8 is schematically shown for clarify and concise description. The remaining pixels may be configured similarly to the first pixel PXL1.

Referring to FIGS. 8 and 10, the first pixel PXL1 may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the light emitting structure EMS (refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3.

The first to third sub-pixels SP1 to SP3 may have an arrangement structure shown in FIG. 10, but embodiments of the present disclosure are not limited thereto.

Referring to FIG. 11, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area greater than that of the first sub-pixel SP1′, and the third sub-pixel SP3′ may have an area greater than that of the second sub-pixel SP2′. Accordingly, the second emission area EMA2′ may have an area greater than the first emission area EMA1′, and the third emission area EMA3′ may have an area greater than that of the second emission area EMA2′. However, embodiments according to the present disclosure are not limited thereto. For example, the first and second sub-pixels SP1′ and SP2′ may have substantially the same area, and the third sub-pixel SP3′ may have an area greater than that of each of the first and second sub-pixels SP1′ and SP2′. As described above, the areas of the first to third sub-pixels SP1′ to SP3′ may vary according to some embodiments.

Referring to FIG. 12, a first sub-pixel SP1″ may include a first emission area EMA1″ and a non-emission area NEA″ around the first emission area EMA1″. A second sub-pixel SP2″ may include a second emission area EMA2″ and a non-emission area NEA″ around the second emission area EMA2″. A third sub-pixel SP3″ may include a third emission area EMA3″ and a non-emission area NEA″ around the third emission area EMA3″.

The first to third sub-pixels SP1″ to SP3″ may have polygonal shapes when viewed in the third direction DR3. For example, shapes of the first to third sub-pixels SP1″ to SP3″ may be hexagonal shapes as shown in FIG. 12.

The first to third emission areas EMA1″ to EMA3″ may have circular shapes when viewed in the third direction DR3. However, embodiments according to the present disclosure are not limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be arranged in a direction inclined by an acute angle based on the second direction DR2 (or a diagonal direction) with respect to the first sub-pixel SP1″.

An arrangement of the sub-pixels shown in FIGS. 10 to 12 is an example, and embodiments according to the present disclosure are not limited thereto. Each pixel may include two or more sub-pixels SP, the sub-pixels SP may be arranged in various methods, the respective sub-pixels may have various shapes, and respective emission areas EMA1, EMA2, and EMA3 thereof may also have various shapes.

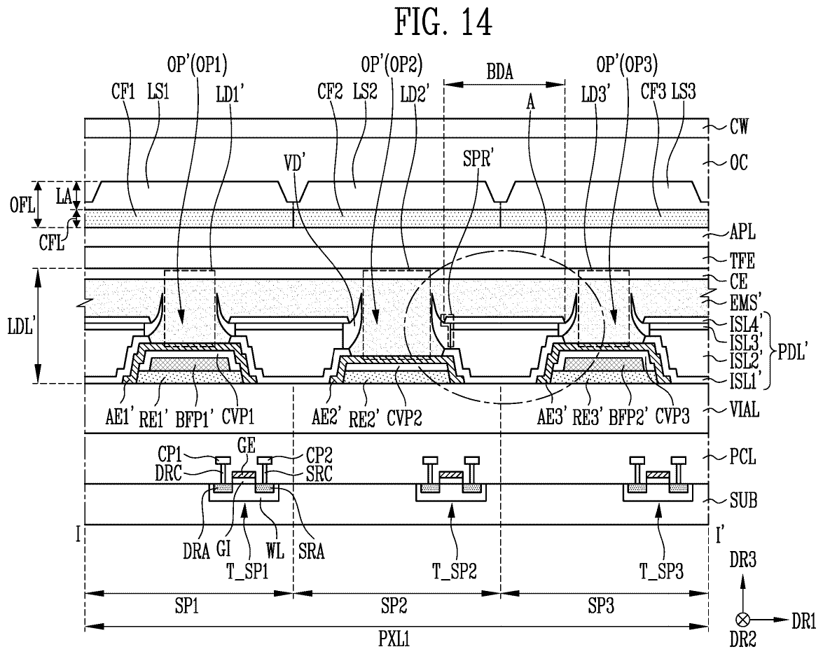

FIG. 13 is a schematic cross-sectional view taken along line I-I′ of FIG. 10. Referring to FIG. 13, the substrate SUB and the pixel circuit layer PCL

located on the substrate SUB are provided.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 13, for clarify and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in the substrate SUB, and the source area SRA and the drain area DRA may be spaced apart from each other in the well WL. An area between the source area SRA and the drain area DRA in the well WL may be defined as a channel area. The gate electrode GE may overlap the channel area between the source area SRA and the drain area DRA and may be located in the pixel circuit layer PCL. The gate electrode GE may be spaced apart from the well WL or the channel area by an insulating material such as a gate insulating layer GI. The gate electrode GE may include a conductive material.

A plurality of layers included in the pixel circuit layer PCL may include insulating layers and conductive patterns located between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL is located on the pixel circuit layer PCL. The via layer VIAL may cover the pixel circuit layer PCL and may have an overall flat surface. The via layer VIAL is configured to planarize steps on the pixel circuit layer PCL. The via layer VIAL may include at least one of silicon oxide (SiOx), silicon nitride (SiNx), or silicon carbon nitride (SiCN), but embodiments according to the present disclosure are not limited thereto.

The light emitting element layer LDL is located on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are located in the first to third sub-pixels SP1 to SP3, respectively. Each of the first to third reflective electrodes RE1 to RE3 may contact the circuit element located in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from them.

According to some embodiments, a connection electrode may be located under each of the first to third reflective electrodes RE1 to RE3. The connection electrode may relatively improve an electrical connection characteristic between a corresponding reflective electrode and the circuit element of the pixel circuit layer PCL. The connection electrode may have a multilayer structure. The multilayer structure may include titanium (Ti), titanium nitride (TiN), tantalum nitride (TaN), or the like, but embodiments according to the present disclosure are not limited thereto. According to some embodiments, a corresponding reflective electrode may be positioned between multiple layers of the connection electrode.

A buffer pattern BFP may be located under at least one of the reflective electrodes RE1 to RE3. The buffer pattern BFP may include an inorganic material such as silicon carbon nitride, but embodiments according to the present disclosure are not limited thereto. By arranging the buffer pattern BFP, a height of the third direction DR3 of a corresponding reflective electrode may be adjusted. For example, the buffer pattern BFP may be located between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. For example, each of the first to third reflective electrodes RE1 to RE3 and the cathode electrode CE may provide a resonance structure in a corresponding sub-pixel. The light emitted from the light emitting layer of the light emitting structure EMS may be amplified by reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light emitting layer of the corresponding light emitting structure EMS.

The first sub-pixel SP1 may have a resonance distance shorter than that of other sub-pixels by the buffer pattern BFP. The resonance distance adjusted described above may allow light of a specific wavelength range (for example, red color) to be effectively and efficiently amplified. Accordingly, the first sub-pixel SP1 may effectively and efficiently output light of a corresponding wavelength range.

In FIG. 13, the buffer pattern BFP provided to the first sub-pixel SP1 and is not provided to the second and third sub-pixels SP2 and SP3, but embodiments according to the present disclosure are not limited thereto. The buffer pattern may also be provided in at least one of the second or third sub-pixels SP2 or SP3 to adjust the resonance distance of at least one of the second or third sub-pixels SP2 or SP3. For example, the first to third sub-pixels SP1 to SP3 may correspond to red, green, and blue, respectively, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize steps between the first to third reflective electrodes RE1 to RE3, the planarization layer PLNL may be located on the via layer VIAL and the first to third reflective electrodes RE1 to RE3. The planarization layer PLNL may generally cover the first to third reflective electrodes RE1 to RE3 and the via layer VIAL, and may have a flat surface. According to some embodiments, the planarization layer PLNL may be omitted.

On the planarization layer PLNL, first to third anode electrodes AE1 to AE3 respectively overlapping the first to third reflective electrodes RE1 to RE3 are located. The first to third anode electrodes AE1 to AE3 may have shapes similar to those of the first to third emission areas EMA1 to EMA3 of FIG. 5 when viewed in the third direction DR3. The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

According to some embodiments, the first to third anode electrodes AE1 to AE3 may include at least one of transparent conductive materials such as indium tin oxide (ITO), indium zinc oxide (IZO), zinc oxide (ZnOx), indium gallium zinc oxide (IGZO), or indium tin zinc oxide (ITZO). However, a material of the first to third anode electrodes AE1 to AE3 is not limited thereto. For example, the first to third anode electrodes AE1 to AE3 may include titanium nitride.

The pixel defining layer PDL is located on portions of the first to third anode electrodes AE1 to AE3 and the planarization layer PLNL. The pixel defining layer PDL has the opening OP exposing a portion of each of the first to third anode electrodes AE1 to AE3. The first opening OP1, the second opening OP2, and the third opening OP3 of the opening OP may correspond to the first opening OP1, the second opening OP2, and the third opening OP3 shown in FIG. 8. An area overlapping the pixel defining layer PDL may be understood as a boundary area BDA between neighboring sub-pixels.

According to some embodiments, the pixel defining layer PDL may include a plurality of inorganic insulating layers. Each of the plurality of inorganic insulating layers may include at least one of silicon oxide (SiOx) or silicon nitride (SiNx). For example, the pixel defining layer PDL may include a first inorganic insulating layer ISL1, a second inorganic insulating layer ISL2, and a third inorganic insulating layer ISL3 that are sequentially stacked. The first to third inorganic insulating layers ISL1 to ISL3 may include silicon nitride, silicon oxide, and silicon nitride, but embodiments according to the present disclosure are not limited thereto. The first to third inorganic insulating layers ISL1 to ISL3 may have a step-shaped cross-section in an area adjacent to the opening OP.

The pixel defining layer PDL may include a separator SPR in the boundary area BDA between neighboring sub-pixels. In other words, the separator SPR may be provided in each of the boundary areas between the sub-pixels SP of FIG. 7.

The separator SPR may cause formation of a discontinuous portion in the light emitting structure EMS in the boundary area BDA. For example, the light emitting structure EMS may be disconnected or bent in the boundary area BDA due to the separator SPR. Therefore, the first to third emission areas EMA1 to EMA3 of FIG. 10 corresponding to the first to third sub-pixels SP1 to SP3 may be defined according to the separator SPR of the pixel defining layer PDL.

The separator SPR may be provided in or on the pixel defining layer PDL. The pixel defining layer PDL may include one or more trenches TRCH1 and TRCH2 as the separator SPR in the boundary area BDA. According to some embodiments, as shown in FIG. 13, one or more trenches TRCH1 and TRCH2 may pass through the pixel defining layer PDL and partially pass through the planarization layer PLNL.

According to some embodiments, one or more trenches TRCH1 and TRCH2 may pass through the pixel defining layer PDL and the planarization layer PLNL, and may partially pass through the via layer VIAL. According to some embodiments, one or more trenches TRCH1 and TRCH2 may at least partially pass through the planarization layer PLNL and/or the via layer VIAL, and a portion of the pixel defining layer PDL may be located in one or more trenches TRCH1 and TRCH2.

In FIG. 13, the two trenches TRCH1 and TRCH2 are provided in the boundary area BDA. However, embodiments according to the present disclosure are not limited thereto. For example, the pixel defining layer PDL may include one trench in the boundary area BDA. Alternatively, the pixel defining layer PDL may include three or more trenches in the boundary area BDA.

Due to the first and second trenches TRCH1 and TRCH2, in the boundary area BDA, discontinuous portions such as a first void VD1 and a second void VD2 may be formed in the light emitting structure EMS. A portion of a plurality of layers stacked in the light emitting structure EMS may be disconnected or bent by the first and second voids VD1 and VD2. For example, at least one charge generation layer and at least one hole injection layer included in the light emitting structure EMS may be disconnected in the first and second voids VD1 and VD2. As described above, portions of the light emitting structure EMS included in the first to third sub-pixels SP1 to SP3 may be at least partially separated due to the first and second trenches TRCH1 and TRCH2.

According to shapes of the first and second trenches TRCH1 and TRCH2, the discontinuous portions formed in the light emitting structure EMS may be variously changed.

According to some embodiments, the light emitting structure EMS may be formed through a process of vacuum deposition, inkjet printing, and the like. In this case, the same materials as the light emitting structure EMS may be positioned on bottom surfaces of the first and second trenches TRCH1 and TRCH2 adjacent to the via layer VIAL.

The pixel defining layer PDL may include an additional separator so that the light emitting structure EMS further includes a discontinuous portion adjacent to the boundary area BDA. According to some embodiments, the third inorganic insulating layer ISL3 of the uppermost portion among the first to third inorganic insulating layers ISL1 to ISL3 of the pixel defining layer PDL may have a width wider than that of the second inorganic insulating layer ISL2 located directly thereunder. For example, the pixel defining layer PDL may have a “T” shape or “I” shape of cross-section in the boundary area BDA. According to a shape of the pixel defining layer PDL, a plurality of layers included in the light emitting structure EMS may be at least partially disconnected or bent in the boundary area BDA or in an area adjacent to the boundary area BDA.

The light emitting structure EMS may be located on the anode electrodes AE1 to AE3 exposed by the opening OP of the pixel defining layer PDL. The light emitting structure EMS may fill the opening OP of the pixel defining layer PDL and may be arranged entirely across the first to third sub-pixels SP1 to SP3. As described above, the light emitting structure EMS may be at least partially disconnected or bent in the boundary area BDA by the separator SPR. Accordingly, when the display panel 110 is operated, a current flowing out from each of the first to third sub-pixels SP1 to SP3 to a sub-pixel adjacent thereto through layers included in the light emitting structure EMS may decrease. Therefore, the first to third light emitting elements LD1 to LD3 may operate with relatively high reliability.

The cathode electrode CE may be located on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping the first anode electrode AE1, and a portion of the cathode electrode CE overlapping the first anode electrode AE1 may configure the first light emitting element LD1. The second anode electrode AE2, a portion of the light emitting structure EMS overlapping the second anode electrode AE2, and a portion of the cathode electrode CE overlapping the second anode electrode AE2 may configure the second light emitting element LD2. The third anode electrode AE3, a portion of the light emitting structure EMS overlapping the third anode electrode AE3, and a portion of the cathode electrode CE overlapping the third anode electrode AE3 may configure the third light emitting element LD3.

The encapsulation layer TFE is located on the cathode electrode CE. The encapsulation layer TFE may prevent or reduce instances of contaminants such as oxygen, moisture, and/or the like permeating to the light emitting element layer LDL.

The optical functional layer OFL is located on the encapsulation layer TFE. According to some embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

According to some embodiments, the first to third color filters CF1 to CF3 may partially overlap in the boundary area BDA. According to some embodiments, the first to third color filters CF1 to CF3 may be spaced apart from each other, and a black matrix may be provided between the first to third color filters CF1 to CF3.

The lens array LA is located on the color filter layer CFL. The lens array LA may include first to third lenses LS1 to LS3 respectively corresponding to the first to third sub-pixels SP1 to SP3. Each of the first to third lenses LS1 to LS3 may relatively improve light output efficiency by outputting light emitted from the first to third light emitting elements LD1 to LD3 to an intended path.

The overcoat layer OC may be located on the lens array LA (or the first to third lenses LS1 to LS3). The overcoat layer OC is configured to protect lower layers thereof from a foreign substance such as dust or moisture. The cover window CW may be located on the overcoat layer OC.

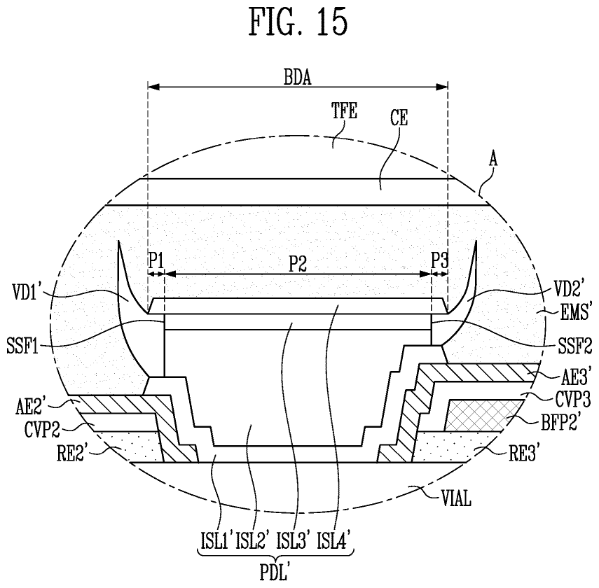

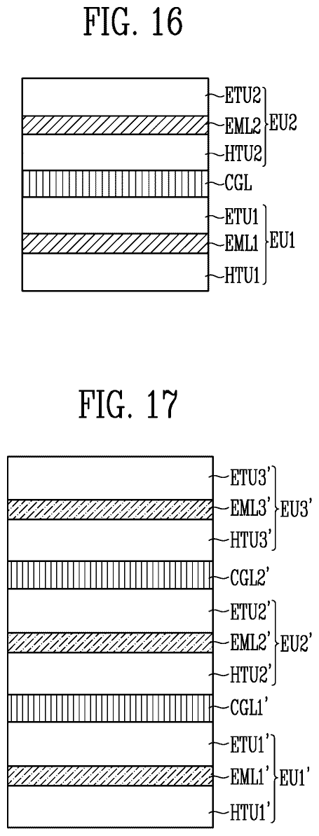

FIG. 14 is a schematic cross-sectional view taken along line I-I′ of FIG. 10 according to some embodiments. FIG. 15 is a schematic enlarged view showing area A of FIG. 14.

Referring to FIG. 14, a pixel circuit layer PCL and a via layer VIAL are located on a substrate SUB. The substrate SUB, the pixel circuit layer PCL, and the via layer VIAL of FIG. 14 are configured similarly to the substrate SUB, the pixel circuit layer PCL, and the via layer VIAL of FIG. 13, respectively. Hereinafter, an overlapping description is omitted.

A light emitting element layer LDL′ is located on the via layer VIAL. The light emitting element layer LDL′ may include first to third reflective electrodes RE1′ to RE3′, first and second buffer patterns BFP1′ and BFP2′, first to third cover patterns CVP1 to CVP3, first to third anode electrodes AE1′ to AE3′, a pixel defining layer PDL′, a light emitting structure EMS′, and a cathode electrode CE.

On the via layer VIAL, the first to third reflective electrodes RE1′ to RE3′ are respectively located in the first to third sub-pixels SP1 to SP3. Each of the first to third reflective electrodes RE1′ to RE3′ may contact a circuit element located in the pixel circuit layer PCL through a via passing through the via layer VIAL.

The first to third reflective electrodes RE1′ to RE3′ are configured to reflect light emitted from the light emitting structure EMS' toward the display surface (or the cover window CW). The first to third reflective electrodes RE1′ to RE3′ may include metal materials suitable for reflecting light. The first to third reflective electrodes RE1′ to RE3′ may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected therefrom, but embodiments according to the present disclosure are not limited thereto.

According to some embodiments, a connection electrode may be further provided between each of the first to third reflective electrodes RE1′ to RE3′ and the via layer VIAL. The connection electrode may relatively improve an electrical connection characteristic between a corresponding reflective electrode and the circuit elements of the pixel circuit layer PCL. The connection electrode may have a multilayer structure. The multilayer structure may include titanium (Ti), aluminum (AI), titanium nitride (TiN), tantalum nitride (TaN), and the like, but embodiments according to the present disclosure are not limited thereto. According to some embodiments, a corresponding reflective electrode may be positioned between multilayers of the connection electrode.

A buffer pattern may be located on at least one of the first to third reflective electrodes RE1′ to RE3′. According to some embodiments, the first and second buffer patterns BFP1′ and BFP2′ may be located on the first and third reflective electrodes RE1′ and RE3′, respectively. Heights of the third direction DR3 of the first and third anode electrodes AE1′ and AE3′ may be adjusted by the first and second buffer patterns BFP1′ and BFP2′. The first and second buffer patterns BFP1′ and BFP2′ may include inorganic material such as silicon oxide (SiOx) and silicon nitride (SiNx), but embodiments according to the present disclosure are not limited thereto.

The first to third cover patterns CVP1 to CVP3 may be located on the first to third reflective electrodes RE1′ to RE3′, respectively. In the first sub-pixel SP1, the first cover pattern CVP1 is located on the first reflective electrode RE1′ and the first buffer pattern BFP1′. In the second sub-pixel SP1, the second cover pattern CVP2 is located on the second reflective electrode RE2′. In the third sub-pixel SP3, the third cover pattern CVP3 is located on the third reflective electrode RE3′ and the second buffer pattern BFP2′. The first to third cover patterns CVP1 to CVP3 may be formed after the first and second buffer patterns BFP1′ and BFP2′ are formed during a manufacturing process. The first to third cover patterns CVP1 to CVP3 may include the same material as the first and second buffer patterns BFP1′ and BFP2′. For example, the first to third cover patterns CVP1 to CVP3 may include an inorganic material such as silicon oxide (SiOx) and silicon nitride (SiNx), but embodiments according to the present disclosure are not limited thereto.

The first to third anode electrodes AE1′ to AE3′ are located on the first to third cover patterns CVP1 to CVP3, respectively. According to some embodiments, the first anode electrode AE1′ may cover the first cover pattern CVP1, the first buffer pattern BFP1′, and the first reflective electrode RE1′. The second anode electrode AE2′ may cover the second cover pattern CVP2 and the second reflective electrode RE2′. The third anode electrode AE3′ may cover the third cover pattern CVP3, the second buffer pattern BFP2′, and the third reflective electrode RE3′.

The first to third anode electrodes AE1′ to AE3′ may be electrically connected to the first to third reflective electrodes RE1′ to RE3′, respectively. For example, each anode electrode may be connected to an end (or an edge) of a corresponding reflective electrode. However, embodiments according to the present disclosure are not limited thereto. In order to relatively improve an electrical connection characteristic between the anode electrode and the reflective electrode, the anode electrode may be connected to the reflective electrode in various methods.

According to some embodiments, the first to third anode electrodes AE1′ to AE3′ may include at least one of transparent conductive materials such as indium tin oxide (ITO), indium zinc oxide (IZO), zinc oxide (ZnOx), indium gallium zinc oxide (IGZO), or indium tin zinc oxide (ITZO). However, a material of the first to third anode electrodes AE1′ to AE3′ is not limited thereto. For example, the first to third anode electrodes AE1′ to AE3′ may include titanium nitride.

The first to third anode electrodes AE1′ to AE3′ may have shapes similar to those of the first to third light emitting regions EMA1 to EMA3 of FIG. 6 when viewed in the third direction DR3.

The first to third anode electrodes AE1′ to AE3′ and the cathode electrode CE may partially reflect incident light. Light emitted from a light emitting layer of the light emitting structure EMS' may be amplified by reciprocating between a corresponding anode electrode and the cathode electrode CE and may be output through the cathode electrode CE. For example, each anode electrode and the cathode electrode CE may provide a resonance structure in a corresponding sub-pixel. In this case, a distance between each anode electrode and the cathode electrode CE may be understood as a resonance distance for a light emitted from a light emitting layer of a corresponding light emitting structure EMS′.

The first to third sub-pixels SP1 to SP3 may correspond to red, green, and blue, respectively. In this case, a height of the third direction DR3 of the first and third anode electrodes AE1′ and AE3′ may be higher than that of the second anode electrode AE2′ by the first and second buffer patterns BFP1′ and BFP2′. Accordingly, the first and third sub-pixels SP1 and SP3 may have a resonance distance shorter than that of the second sub-pixel SP2 by the first and second buffer patterns BFP1′ and BFP2′. As described above, a resonance distance of each sub-pixel may be adjusted so that light of a wavelength range of a corresponding color is effectively and efficiently amplified.

In FIG. 14, the first and second buffer patterns BFP1′ and BFP2′ are respectively located under the first and third anode electrodes AE1′ and AE3′, but embodiments according to the present disclosure are not limited thereto. For example, one of the first and second buffer patterns BFP1′ and BFP2′ may be omitted. As another example, both of the first and second buffer patterns BFP1′ and BFP2′ may be omitted. In this case, the resonance distance between each anode electrode and the cathode electrode CE may be the same. As still another example, a buffer pattern may be located under each of the first to third anode electrodes AE1′ to AE3′. In this case, the buffer pattern located under each anode electrode may have different thicknesses, and thus the resonance distances between each anode electrode and the cathode electrode CE may be different from each other. As described above, by providing a buffer pattern for adjusting a height of a corresponding anode electrode under at least one of the first to third anode electrodes AE1′ to AE3′, a resonance distance in each sub-pixel may be optimized.

The pixel defining layer PDL′ is located on portions of the first to third anode electrodes AE1′ to AE3′ and the via layer VIAL. The pixel defining layer PDL′ has an opening OP′ that exposes a portion of each of the first to third anode electrodes AE1′ to AE3′. A first opening OP1′, a second opening OP2′, and a third opening OP3′ of the openings OP′ may correspond to the first opening OP1, the second opening OP2, and the third opening OP3 shown in FIG. 8. An area overlapping the pixel defining layer PDL′ may be understood as a boundary area BDA between neighboring sub-pixels.

The pixel defining layer PDL′ may include a plurality of sequentially stacked inorganic insulating layers. Each of the plurality of inorganic insulating layers may include at least one of silicon oxide (SiOx) or silicon nitride (SiNx). However, embodiments according to the present disclosure are not limited thereto. For example, the pixel defining layer PDL′ may include an organic insulating layer.

According to some embodiments, the pixel defining layer PDL′ may include first to fourth inorganic insulating layers ISL1′ to ISL4′. The first inorganic insulating layer ISL1′ may cover portions of the first to third anode electrodes AE1′ to AE3′ and the via layer VIAL. The second inorganic insulating layer ISL2′ is located on the first inorganic insulating layer ISL1′, the third inorganic insulating layer ISL3′ is located on the second inorganic insulating layer ISL2′, and the fourth inorganic insulating layer ISL4′ is located on the third inorganic insulating layer ISL3′. The first and third inorganic insulating layers ISL1′ and ISL3′ may include silicon nitride (SiNx), and the second and fourth inorganic insulating layers ISL2′ and ISL4′ may include silicon oxide (SiOx), but embodiments according to the present disclosure are not limited thereto. According to some embodiments, the first inorganic insulating layer ISL1′ may be omitted.

The pixel defining layer PDL′ may include a separator SPR′ in the boundary area BDA between neighboring sub-pixels. The separator SPR′ may cause a discontinuous portion such as a void VD′ to be formed in the light emitting structure EMS′. Due to the discontinuous portion, at least a portion of layers included in the light emitting structure EMS' may be disconnected or bent.

The fourth inorganic insulating layer ISL4′ may have a width wider than that of the second and third inorganic insulating layers ISL2′ and ISL3′. In this case, side surfaces of the second to fourth inorganic insulating layers ISL2′ to ISL4′ adjacent to the opening OP′ may be provided as the separator SPR′.

Referring to FIG. 15 together with FIG. 14, the fourth inorganic insulating layer ISL4′ may include first to third portions P1 to P3. The second portion P2 may completely overlap the second and third inorganic insulating layers ISL2′ and ISL3′. The first portion P1 protrudes from the second portion P2 in a direction opposite to the first direction DR1. The third portion P3 protrudes from the second portion P2 in the first direction DR1. As described above, a width of the fourth inorganic insulating layer ISL4′ may be wider than that of the second and third inorganic insulating layers ISL2′ and ISL3′. For example, during a manufacturing process, the second and third inorganic insulating layers ISL2′ and ISL3′ may be undercut so as not to include a portion overlapping the first and third portions P1 and P3. For example, each of the first and third portions P1 and P3 of the fourth inorganic insulating layer ISL4′ may have a shape of eaves on the second and third inorganic insulating layers ISL2′ and ISL3′.

In the boundary area BDA, the second and third inorganic insulating layers ISL2′ and ISL3′ may have the same width. However, embodiments are not limited thereto, and the second and third inorganic insulating layers ISL2′ and ISL3′ may have different widths. For example, the second inorganic insulating layer ISL2′ may have a width wider than that of the third inorganic insulating layer ISL3′. As another example, the third inorganic insulating layer ISL3′ may have a width wider than that of the second inorganic insulating layer ISL2′.

In the second sub-pixel SP2, the first portion P1 of the fourth inorganic insulating layer ISL4′ and a first side surface SSF1 of the second and third inorganic insulating layers ISL2′ and ISL3′ may be provided as one separator SPR′. Accordingly, a first void VD1′ adjacent to the first portion P1 of the fourth inorganic insulating layer ISL4′ in the light emitting structure EMS' may be formed. In the third sub-pixel SP3, the third portion P3 of the fourth inorganic insulating layer ISL4′ and a second side surface SSF2 of the second and third inorganic insulating layers may be provided as another separator SPR′. Accordingly, a second void VD2′ adjacent to the third portion P3 of the fourth inorganic insulating layer ISL4′ in the light emitting structure EMS' may be formed.

A portion of a plurality of layers stacked in the light emitting structure EMS' may be disconnected or bent by the first and second voids VD1′ and VD2′. For example, at least one charge generation layer and at least one hole injection layer included in the light emitting structure EMS' may be disconnected by the first and second voids VD1′ and VD2′. As described above, due to the separator SPR′, portions of the light emitting structure EMS' included in the first to third sub-pixels SP1 to SP3 may be at least partially separated from each other.

The pixel defining layer PDL′ may include an additional separator so that the light emitting structure EMS' further includes a discontinuous portion in the boundary area BDA. According to some embodiments, the pixel defining layer PDL′ may include one or more trenches as a separator in the boundary area BDA. The trenches may pass through one or more of the first to fourth inorganic insulating layers ISL1′ to ISL4′. Due to the trenches, a portion of the plurality of layers stacked in the light emitting structure EMS′, for example, at least one charge generation layer and at least one hole injection layer, may be disconnected or bent. According to some embodiments, the light emitting structure EML′ may have a structure in which three light emitting units, each including an light emitting layer, are stacked, and two charge generation layers may be located between the three light emitting units. In these embodiments, the pixel defining layer PDL′ may include one or more trenches in the boundary area BDA.

Referring to FIG. 14 again, the light emitting structure EMS' may be located on the anode electrodes AE exposed by the opening OP′ of the pixel defining layer PDL′. The light emitting structure EMS' may fill the opening OP′ of the pixel defining layer PDL′ and may be arranged entirely over the first to third sub-pixels SP1 to SP3. As described above, the light emitting structure EMS' may be disconnected or bent by the separator SPR′ in the boundary area BDA or in an area adjacent to the boundary area BDA. Accordingly, when the display panel 110 is operated, current flowing from each of the first to third sub-pixels SP1 to SP3 to a sub-pixel neighboring each of the first to third sub-pixels SP1 to SP3 through the layers included in the light emitting structure EMS' may be reduced. Therefore, first to third light emitting elements LD1′ to LD3′ may operate with relatively high reliability.

According to some embodiments, the light emitting structure EMS' may include two light emitting units sequentially stacked, and each of the light emitting units may include a light emitting layer configured to generate light according to an applied current. According to some embodiments, the light emitting structure EMS' may include three light emitting units sequentially stacked, and each of the light emitting units may include a light emitting layer configured to generate light according to an applied current. In these embodiments, a charge generation layer may be located between the light emitting units.

According to some embodiments, the light emitting structure EMS' may be formed through a process of vacuum deposition, inkjet printing, and the like.

The cathode electrode CE may be located on the light emitting structure EMS′. The cathode electrode CE may be commonly provided to the first to third sub-pixels SP1 to SP3.

The first anode electrode AE1′, a portion of a light emitting structure EMS' overlapping the first anode electrode AE1′, and a portion of the cathode electrode CE overlapping the first anode electrode AE1′ may configure the first light emitting element LD1′. The second anode electrode AE2′, a portion of the light emitting structure EMS' overlapping the second anode electrode AE2′, and a portion of the cathode electrode CE overlapping the second anode electrode AE2′ may configure the second light emitting element LD2′. The third anode electrode AE3′, a portion of the light emitting structure EMS' overlapping the third anode electrode AE3′, and a portion of the cathode electrode CE overlapping the third anode electrode AE3′ may configure the third light emitting element LD3′.

The encapsulation layer TFE is located on the cathode electrode CE. The encapsulation layer TFE may prevent or reduce instances of contaminants such as oxygen, moisture, and/or the like penetrating into the light emitting element layer LDL′.

The adhesive layer APL, the optical functional layer OFL, the overcoat layer OC, and the cover window CW are located on the encapsulation layer TFE. The adhesive layer APL, the optical functional layer OFL, the overcoat layer OC, and the cover window CW are configured similarly to the adhesive layer APL, the optical functional layer OFL, the overcoat layer OC, and the cover window CW of FIG. 13, respectively. An overlapping description of these is omitted.

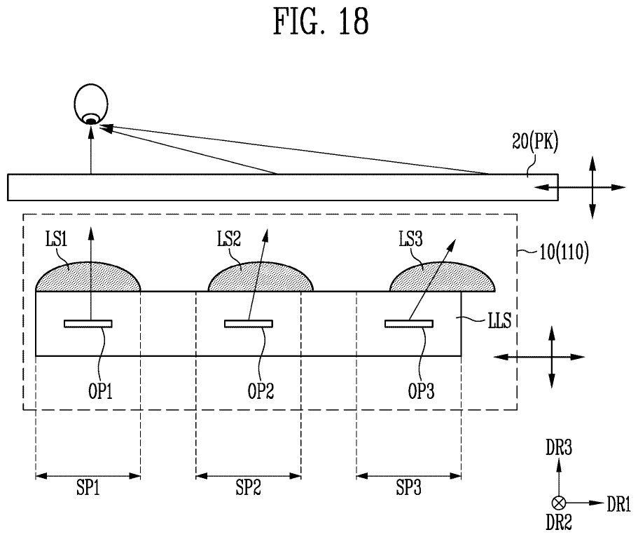

FIG. 16 is a schematic cross-sectional view illustrating an example of a portion of a light emitting structure included in one of the first to third light emitting elements of FIG. 13 or 14.

Referring to FIG. 16, the light emitting structure may have a tandem structure in which first and second light emitting units EU1 and EU2 are stacked. The light emitting structure may be configured substantially equally in each of the first to third light emitting elements LD1 to LD3 of FIG. 14.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be located between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be located between the second electron transport unit ETU2 and the second hole transport unit HTU2.

Each of the first and second hole transport units HTU1 and HTU2 may include at least one of a hole injection layer or a hole transport layer, and may further include a hole buffer layer, an electron blocking layer, and the like if necessary. The first and second hole transport units HTU1 and HTU2 may have configurations equal to each other or different from each other.

Each of the first and second electron transport units ETU1 and ETU2 may include at least one of an electron injection layer or an electron transport layer, and may further include an electron buffer layer, a hole blocking layer, and the like if necessary. The first and second electron transport units ETU1 and ETU2 may have configurations equal to each other or different from each other.

A connection layer, which may be provided in a form of a charge generation layer CGL, may be located between the first light emitting unit EU1 and the second light emitting unit EU2 to connect the first light emitting unit EU1 and the second light emitting unit EU2 to each other. According to some embodiments, the charge generation layer CGL may have a stack structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide metal, or a combination thereof. However, embodiments according to the present disclosure are not limited thereto.

According to some embodiments, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate blue light, and the second light emitting layer EML2 may generate yellow light. According to some embodiments, the second light emitting layer EML2 may include a structure in which a first sub light emitting layer configured to generate red light and a second sub light emitting layer configured to generate green light are stacked. The red light and the green light may be mixed, and thus the yellow light may be provided. In this case, an intermediate layer configured to perform a function of transporting holes and/or blocking transport of electrons may be further located between the first and second sub light emitting layers.

According to some embodiments, the first light emitting layer EML1 and the second light emitting layer EML2 may generate light of the same color.

The light emitting structure may be formed through a method of vacuum deposition, inkjet printing, and the like, but embodiments according to the present disclosure are not limited thereto.

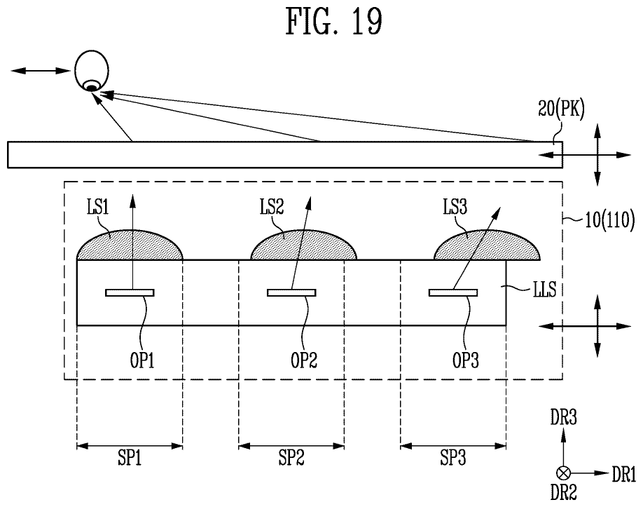

FIG. 17 is a schematic cross-sectional view illustrating further details of a portion of a light emitting structure included in one of the first to third light emitting elements of FIG. 13 or 14.

Referring to FIG. 17, the light emitting structure may have a tandem structure in which first to third light emitting units EU1′ to EU3′ are stacked. The light emitting structure may be configured substantially equally in each of the first to third light emitting elements LD1 to LD3 of FIG. 13.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be located between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be located between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be located between the third electron transport unit ETU3′ and the third hole transport unit HTU3′.

Each of the first to third hole transport units HTU1′ to HTU3′ may include at least one of a hole injection layer or a hole transport layer, and may further include a hole buffer layer, an electron blocking layer, and the like if necessary. The first to third hole transport units HTU1′ to HTU3′ may have configurations equal to each other or different from each other.

Each of the first to third electron transport units ETU1′ to ETU3′ may include at least one of an electron injection layer or an electron transport layer, and may further include an electron buffer layer, a hole blocking layer, and the like, if necessary. The first to third electron transport units ETU1′ to ETU3′ may have configurations equal to each other or different from each other.

A first charge generation layer CGL1′ is located between the first light emitting unit EU1′ and the second light emitting unit EU2′. A second charge generation layer CGL2′ is located between the second light emitting unit EU2′ and the third light emitting unit EU3′.

According to some embodiments, the first to third light emitting layers EML1′ to EML3′ may generate light of different colors. Light emitted from each of the first to third light emitting layers EML1′ to EML3′ may be mixed and may be viewed as white light. For example, the first emitting layer EML1′ may generate light of a blue color, the second emitting layer EML2′ may generate light of a green color, and the third emitting layer EML3′ may generate light of a red color.

According to some embodiments, two or more of the first to third light emitting layers EML1′ to EML3′ may generate light of the same color.

Differently from that shown in FIGS. 16 and 17, the light emitting structure of FIG. 13 or 14 may include one light emitting unit in each of the first to third light emitting elements LD1 to LD3. At this time, the light emitting unit included in each of the first to third light emitting elements LD1 to LD3 may be configured to emit light of different colors. For example, the light emitting unit of the first light emitting element LD1 may emit the light of the red color, the light emitting unit of the second light emitting element LD2′ may emit the light of the green light, and the light emitting unit of the third light emitting element LD3 may emit the light of the blue color. In this case, the light emitting units of the first to third sub-pixels SP1 to SP3 may be separated from each other, and each of them may be located in the opening (refer to OP of FIG. 13 and OP′ of FIG. 14) of the pixel defining layer (refer to PDL of FIG. 13 or PDL′ of FIG. 14). In this case, at least a portion of the color filters CF1 to CF3 may be omitted.

Hereinafter, movement of the display unit 10 and the optical unit 20 according to the user's pupil position is described with reference to FIGS. 18 to 20.

FIGS. 18 to 20 are schematic drawings illustrating the movement of the display unit and the optical unit according to the user's pupil position. In FIGS. 18 to 20, an area where the first sub-pixel SP1 is located corresponds to the central area of the display panel 110, and may face the outer area of the display panel 110 in the first direction DR1. However, embodiments of the present disclosure are not limited thereto, and according to some embodiments, the pixel located in the central area of the display panel 110 may be the second sub-pixel SP2 or the third sub-pixel SP3.

FIG. 18 shows a case where the user's pupil is positioned at a first position, FIG. 19 shows a case where the user's pupil swims and is positioned at a second position, and FIG. 20 shows a case where the user's eye rotates and the pupil is positioned at a third position. The first position means a position where the center of the user's pupil coincides with at least one of the center of the display panel 110 of the display unit 10 or the center of the pancake lens PK of the optical unit 20. According to some embodiments, a virtual line extending from the center of the user's pupil at the first position (hereinafter, a pupil center axis) may form a 90° with the display panel 110 or the pancake lens PK. The second position means a position moved horizontally (for example, in the first direction DR1 or the second direction DR2) with respect to the first position. For example, the center of the pupil may move from the first position in the first direction DR1 or the second direction DR2 and may be positioned at the second position. The third position means a position rotated by an angle with respect to the first position. For example, the center of the pupil may move by rotating by the angle from the first position as the user's eye rotates, and may be positioned at the third position.

Referring to FIG. 18, when the user's pupil is positioned at the first position, at least one of the display unit 10 or the optical unit 20 may be moved. Based on the information on the user's pupil position and the gaze direction, at least one of the display unit 10 or the optical unit 20 may be moved.

When the user's pupil is positioned at the first position, the display panel 110 and the pancake lens PK may be suitably positioned at a position that appropriately forms a focus on the pupil positioned at the first position. The position of the display panel 110 and the pancake lens PK for appropriately forming a focus on the pupil positioned at the first position may be determined by information input to the display device 1 through simulation.

According to some embodiments, the display device 1 may determine the position of one of the display panel 110 and the pancake lens PK based on the information on the user's pupil position and the gaze direction, and then determine the position of the other one. For example, the display device 1 may determine the position of the display panel 110 based on the information on the user's pupil position and the gaze direction, and then determine the position of the pancake lens PK. Alternatively, the display device 1 may determine the position of the pancake lens PK based on the information on the user's pupil position and the gaze direction, and then determine the position of the display panel 110.

For example, after the center of the display panel 110 and the center of the user's pupil are arranged to coincide with each other, the pancake lens PK may be moved to coincide with the center of the user's pupil. The lens movement unit 20_M may move the pancake lens PK in the direction in which the plane where the pancake lens PK is located extends (for example, the first direction DR1 or the second direction DR2 as the left-right direction) and the direction perpendicular to the plane where the pancake lens PK is located (for example, the third direction DR3 as the up-down direction) based on information on a distance from the display panel 110, a distance from the user's pupil (or eye), and an angle with respect to the center axis of the user's pupil.

Alternatively, after the center of the pancake lens PK and the center of the user's pupil are located to coincide with each other, the display panel 110 may be moved to coincide with the center of the user's pupil. The panel movement unit 10_M may move the display panel 110 in the direction in which the plane where the display panel 110 is located extends (for example, the first direction DR1 or the second direction DR2 as the left-right direction) and the direction perpendicular to the plane where the display panel 110 is located (for example, the third direction DR3 as the up-down direction) based on the information on a distance from the pancake lens PK, the distance from the user's pupil, and the angle with respect to the center axis of the user's pupil.

As described above, according to some embodiments, when the user's pupil is at the first position, the panel movement unit 10_M may move the display panel 110 in order to cause the center of the user's pupil and the center of the display panel 110 to coincide with each other. According to some embodiments, when the user's pupil is at the first position, the lens movement unit 20_M may move the pancake lens PK to cause the center of the user's pupil and the center of the pancake lens PK to coincide with each other.

Referring to FIG. 19, when the user's pupil swims and moves to the second position, the display unit 10 and the optical unit 20 may be moved. The display device may sense that information on the user's pupil position and the gaze direction changes, and generate a signal for moving the display unit 10 and the optical unit 20.

The user's pupil may swim and move in parallel in the first direction DR1 by one distance from the first position and may be positioned at the second position. At this time, when the display panel 110 and the pancake lens PK are positioned at the same position as that shown in FIG. 18, appropriately forming a focus on the user by light emitted from the display panel 110 may be difficult. Therefore, when the position of the user's pupil changes, the display panel 110 and the pancake lens PK may be moved.

For example, the display panel 110 may be moved so that the center of the display panel 110 and the center of the user's pupil coincide with each other. The panel movement unit 10_M may move the display panel 110 in the direction in which the plane where the display panel 110 is located extends (for example, the first direction DR1 or the second direction DR2 as the left-right direction) and the direction perpendicular to the plane where the display panel 110 is located (for example, the third direction DR3 as the up-down direction) based on the information on the distance from the pancake lens PK, the distance from the user's pupil, and the angle with respect to the center axis of the user's pupil.

The pancake lens PK may be moved so that the center of the pancake lens PK and the center of the user's pupil coincide with each other. The lens movement unit 20_M may move the pancake lens PK in the direction in which the plane where the pancake lens PK is located extends (for example, the first direction DR1 or the second direction DR2 as the left-right direction) and the direction perpendicular to the plane where the pancake lens PK is located (for example, the third direction DR3 as the up-down direction) based on the information on the distance from the display panel 110, the distance from the user's pupil, and the angle with respect to the center axis of the user's pupil.

Referring to FIG. 20, when the user's eye rotates and the pupil moves to the third position, the display panel 110 and the pancake lens PK may be moved to a position for appropriately forming a focus on the user's eye positioned at the third position. The display device 1 may sense a change in the information on the user's pupil position and the gaze direction, and generate a signal for moving the display panel 110 and the pancake lens PK.

The display device 1 may move the display panel 110 based on an input simulation result. The panel movement unit 10_M moves the display panel 110 in the direction in which the plane where the display panel 110 is located extends (for example, the first direction DR1 or the second direction DR2 as the left-right direction) and the direction perpendicular to the plane where the display panel 110 is located (for example, the third direction DR3 as the up-down direction) based on the information on the distance from the pancake lens PK, the distance from the user's pupil, and the angle with respect to the center axis of the user's pupil.

The display device 1 may move the pancake lens PK based on the input simulation result. The lens movement unit 20_M may move the pancake lens PK in the direction in which the plane where the pancake lens PK is located extends (for example, the first direction DR1 or the second direction DR2 as the left-right direction) and the direction perpendicular to the plane where the pancake lens PK is located (for example, the third direction DR3 as the up-down direction) based on the information on the distance from the display panel 110, the distance from the user's pupil, and the angle with respect to the center axis of the user's pupil.

According to some embodiments, the case movement unit 30_M may be further operated when the user's eye is positioned at the first position, the second position, and the third position. For example, the case movement unit 30_M may rotate the case unit 30 by one angle that the user's eye rotates. For example, the display panel 110 and the pancake lens PK may be rotated so that the center of the display panel 110 and the center of the pancake lens PK coincide with the center of the user's pupil.

The display device 1 according to the disclosure may move the display unit 10 (or the display panel 110, the optical unit 20 (or the pancake lens PK), and the case unit 30) based on the user's pupil position and the direction of the gaze. Accordingly, an appropriate eye relief distance may be secured, the distance between the display units 10 and the distance between the optical units 20 may be appropriately adjusted, and the angle formed between the display unit 10 and the optical unit 20 and the user's eye may be appropriately adjusted. Accordingly, an image or picture with relatively improved display quality may be provided to the user.

A display device according to an embodiment is applicable to various types of electronic devices. In an embodiment, an electronic device includes the above-described display device and may further include other modules or devices having additional functions in addition to the display device.

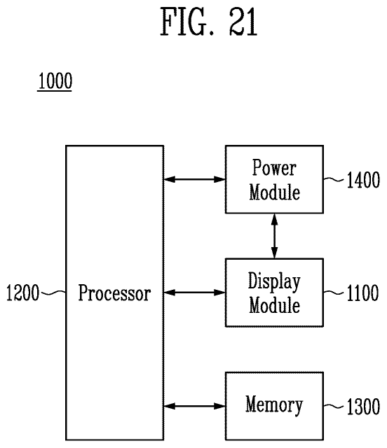

FIG. 21 is a block diagram of an electronic device according to an embodiment. Referring to FIG. 21, the electronic device 1000 may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The memory 1300 may store data and/or information used to operate the processor 1200 or the display module 1100. When the processor 1200 executes an application stored in the memory 1300, image data signals and/or input control signals may be transferred to the display module 1100. The display module 1100 may process the provided signals and output image information on a display screen.

The power module 1400 may include a power supply module, such as a power adapter or a battery device, and a power conversion module. The power conversion module converts power supplied by the power supply module and generates power to operate the electronic device 1000.

At least one of the above-described components of the electronic device 1000 may be included in the display device according to embodiments as described above. In addition, in terms of functionality, some of the individual modules included in one module may be included in the display device and others may be provided separately from the display device. For example, the display module 1100 is included in the display device, whereas the processor 1200, the memory 1300, and the power module 1400 are not included in the display device and are instead provided separately in the electronic device 1000.

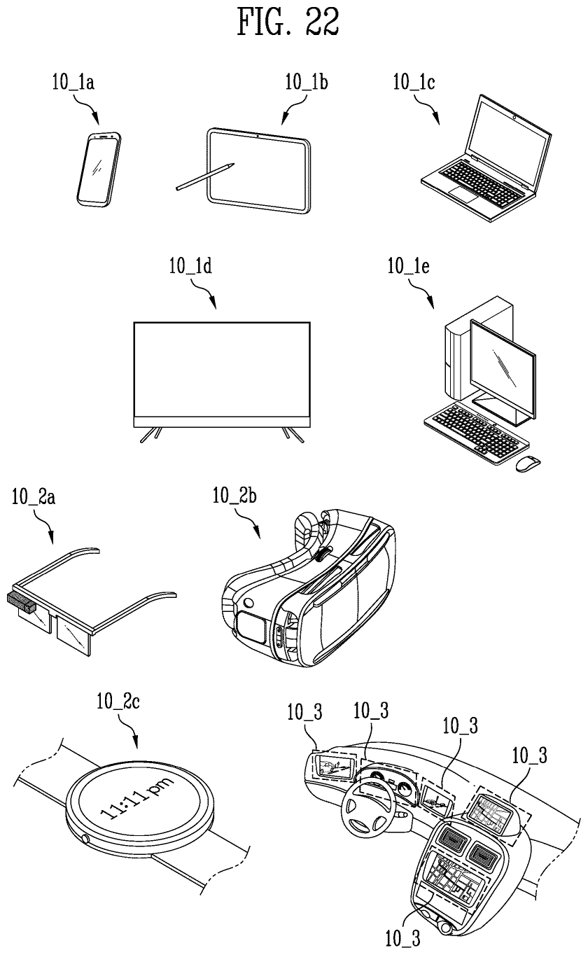

FIG. 22 shows schematic views of various embodiments of an electronic device.

Referring to FIG. 22, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

As described above, although the disclosure has been described with reference to the disclosed embodiments above, those skilled in the art or those having a common knowledge in the art will understand that the disclosure may be variously modified and changed without departing from the spirit and technical area of the disclosure described in the claims, and their equivalents.

Therefore, the technical scope of embodiments according to the present disclosure should not be limited to the contents described in the detailed description of the specification, but should be defined by the appended claims, and their equivalents.

What is claimed is:

1. A display device comprising:
a display unit including a first surface configured to emit light in a first direction and a second surface opposite to the first surface;
an optical unit on the first surface of the display unit,
wherein the display unit comprises a display panel which comprises:
a first sub-pixel, a second sub-pixel, and a third sub-pixel;
a pixel defining layer including a first opening, a second opening, and a third opening defining an emission area of the first to third sub-pixels, respectively; and
a first lens, a second lens, and a third lens on the pixel defining layer;
the optical unit comprises:
a lens unit configured to transmit the light;
a first infrared light source; and
a camera,
the display device further comprises a lens movement unit configured to move the lens unit,
at least one of a center of the first lens and a center of the first opening, a center of the second lens and a center of the second opening, or a center of the third lens and a center of the third opening do not coincide with each other.

2. The display device according to claim 1, wherein the lens unit includes a pancake lens, and
the pancake lens comprises:
a first polarizing layer;
a first quarter wave plate;
a partial reflection mirror layer;
a second quarter wave plate; and
a second polarizing layer.

3. The display device according to claim 2, wherein the first sub-pixel is at a center of the display panel,
the center of the first lens and the center of the first opening overlap in a plan view,
the center of the second lens is shifted by a first distance from the center of the second opening, and
the center of the third lens is shifted by a second distance different from the first distance from the center of the third opening.

4. The display device according to claim 3, comprising:
an overcoat layer on the first lens,
wherein each of the first lens, the second lens, and the third lens has a refractive index higher than that of the overcoat layer.

5. The display device according to claim 1, wherein the display device is configured to be worn by a user, and
in a worn state, the camera is configured to detect a position of a user's pupil through light emitted from the first infrared light source reflected on the user's pupil.

6. The display device according to claim 5, wherein the lens movement unit is configured to move the lens unit in at least one of a direction in which a plane on which the lens unit is located extends or a direction perpendicular to the plane, based on the position of the user's pupil.

7. The display device according to claim 5, further comprising:
a panel movement unit configured to move the display panel,
wherein the panel movement unit is configured to move the display panel in at least one of a direction in which a plane on which the display panel is located extends or a direction perpendicular to the plane, based on the position of the user's pupil.

8. The display device according to claim 1, further comprising:
a case unit in which the display unit and the optical unit are received; and
a case movement unit configured to rotate the case unit.

9. The display device according to claim 1, wherein the display device is an OLED on silicon (OLEDoS) display device.

10. A head mounted display device comprising:
a display unit including a first surface configured to emit light in a first direction and a second surface opposite to the first surface; and
an optical unit on the first surface of the display unit,
wherein the display unit comprises a display panel which comprises:
a first sub-pixel, a second sub-pixel, and a third sub-pixel;
a pixel defining layer including a first opening, a second opening, and a third opening defining an emission area of the first to third sub-pixels, respectively; and
a first lens, a second lens, and a third lens on the pixel defining layer,
a lens unit configured to transmit the light;
a first infrared light source; and
a camera,
the head mounted display device further comprises:
a lens movement unit configured to move the lens unit; and
a panel movement unit configured to move the display panel,
in a worn state of the head mounted display device, the camera is configured to detect a position of a user's pupil through light emitted from the first infrared light source reflected on the user's pupil,
at least one of a center of the first lens and a center of the first opening, a center of a second lens and a center of the second opening, or a center of the third lens and a center of the third opening do not coincide with each other, and
the lens movement unit and the panel movement unit are configured to move the lens unit and the display panel, respectively, according to the position of the user's pupil.

11. The head mounted display device according to claim 10, wherein the lens unit includes a pancake lens, and
the pancake lens comprises:
a polarizing layer;
a quarter wave plate; and
a partial reflection mirror layer, and
at least one surface of the polarizing layer, the quarter wave plate, and the partial reflection mirror layer is a curved surface.

12. The head mounted display device according to claim 11, wherein the first sub-pixel is at a center of the display panel,
the center of the first lens and the center of the first opening overlap in a plan view,
the center of the second lens is shifted from the center of the second opening by a first distance, and
the center of the third lens is shifted from the center of the third opening by a second distance different from the first distance.

13. The head mounted display device according to claim 12, comprising:
an overcoat layer on the first lens,
wherein each of the first lens, the second lens, and the third lens has a refractive index higher than that of the overcoat layer.

14. The head mounted display device according to claim 10, further comprising:
a case unit in which the display unit and the optical unit are received;
a fix unit configured to mount the case unit on a user's head; and
a case movement unit between the fix unit and the case unit,
wherein the case movement unit is configured to rotate the case unit to adjust an angle formed by the lens unit and the display panel with a central axis of the user's pupil.

15. The head mounted display device according to claim 10, wherein based on the user's pupil being at a first position, the panel movement unit is configured to move the display panel to cause a center of the user's pupil and a center of the display panel to coincide with each other, and
the lens movement unit is configured to move the lens unit to cause the center of the user's pupil and a center of the lens unit to coincide with each other.

16. The head mounted display device according to claim 10, wherein the display unit includes a first display unit including a first display panel and a second display unit including a second display panel,
the optical unit includes a first optical unit including a first lens unit and a second optical unit including a second lens unit,
the panel movement unit includes a first panel movement unit configured to move the first display panel and a second panel movement unit moving the second display panel, and
the lens movement unit includes a first lens movement unit moving the first lens unit and a second lens movement unit moving the second lens unit.

17. The head mounted display device according to claim 16, wherein the first lens movement unit and the second lens movement unit are configured to move the first lens unit and the second lens unit, respectively, so that at least one of a distance between the first lens unit and the second lens unit, or a distance between each of the first lens unit and the second lens unit and a user's eye is configured to be adjusted, based on the position of the user's pupil, and
the first panel movement unit and the second panel movement unit are configured to move the first display panel and the second display panel, respectively, so that at least one of a distance between the first display panel and the second display panel, or a distance between each of the first display panel and the second display panel and the user's eye is configured to be adjusted, based on the position of the user's pupil.

18. The head mounted display device according to claim 10, wherein the display panel includes a silicon substrate.

19. An electronic device comprising:
a processor and a display device,
wherein the display device comprises:
a display unit including a first surface configured to emit light in a first direction and a second surface opposite to the first surface;
an optical unit on the first surface of the display unit,
wherein the display unit comprises a display panel which comprises:
a first sub-pixel, a second sub-pixel, and a third sub-pixel;
a pixel defining layer including a first opening, a second opening, and a third opening defining an emission area of the first to third sub-pixels, respectively; and
a first lens, a second lens, and a third lens on the pixel defining layer;
the optical unit comprises:
a lens unit configured to transmit the light;
a first infrared light source; and
a camera,
the display device further comprises a lens movement unit configured to move the lens unit,
at least one of a center of the first lens and a center of the first opening, a center of the second lens and a center of the second opening, or a center of the third lens and a center of the third opening do not coincide with each other.
